(19) United States
(12) Patent Application Publication
(10) Pub. No.: US 2025/0203955 A1
(43) Pub. Date: Jun. 19, 2025

(54) FIELD EFFECT TRANSISTOR HAVING REPLACEMENT SOURCE/DRAINS AND RELATED METHODS

(71) Applicant: Taiwan Semiconductor Manufacturing Co., Ltd., Hsinchu (TW)

(72) Inventors: Hsien-Chih HUANG, Hsinchu (TW); Guan-Lin CHEN, Hsinchu (TW); Chia-Hao YU, Hsinchu (TW); Pei-Yu WANG, Hsinchu (TW); Chih-Hao WANG, Hsinchu (TW)

(21) Appl. No.: 18/733,656

(22) Filed: Jun. 4, 2024

Related U.S. Application Data
(60) Provisional application No. 63/611,898, filed on Dec. 19, 2023.

(51) Int. Cl. H01L 29/78; H01L 21/02; H01L 29/06; H01L 29/08; H01L 29/40; H01L 29/417; H01L 29/423; H01L 29/45; H01L 29/49; H01L 29/66; H01L 29/775; H01L 29/786

(52) U.S. Cl. CPC H10D 30/797; H01L 21/02532; H01L 21/02535; H10D 30/014; H10D 30/43; H10D 30/6729; H10D 30/6735; H10D 30/6757; H10D 62/121; H10D 62/151; H10D 64/017; H10D 64/62; H10D 64/679

(57) ABSTRACT

A device and method of forming a device are provided. The method includes forming a stack of nanostructure channels over a substrate by forming a source/drain opening. The method also includes forming a sacrificial source/drain in the source/drain opening. The method further includes increasing tensile strain of the stack of nanostructure channels by replacing the sacrificial source/drain with a replacement source/drain having germanium concentration that exceeds that of the sacrificial source/drain.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrammatic cross-sectional side views of a portion of an IC device according to embodiments of the present disclosure.

FIGS. 2A-23 are views of various embodiments of an IC device of at various stages of fabrication according to various aspects of the present disclosure.

FIG. 24 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source or a drain, individually or collectively dependent upon the context.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

In nanosheet FETs, SiGe can be used as a semiconductor material for source/drains. To avoid epitaxial damage during source/drain formation, a SiB layer and lower Ge concentration SiGe layer are grown first before a high Ge concentration layer can be grown. This reduces the strain that can be applied to the channel, leading to a degradation in transistor current.

Embodiments of the disclosure form a SiGe sacrificial source/drain which is later replaced in favor of a pure Ge or high Ge concentration source/drain. As such, lattice constant can be increased, strain applied to the channel is increased and drive current is increased. The pure or high concentration Ge source/drain can also lower source/drain contact resistance, which is beneficial to boost current output.

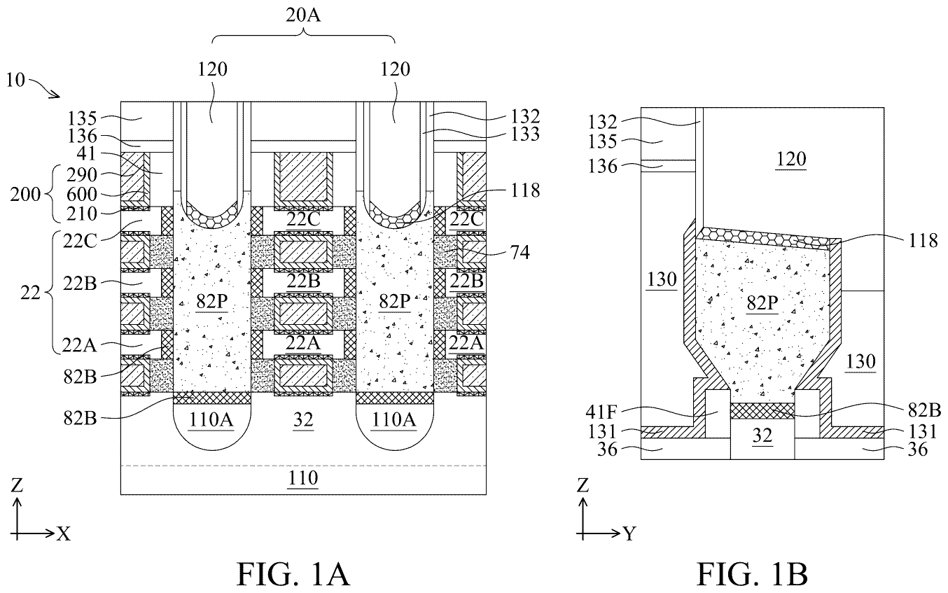

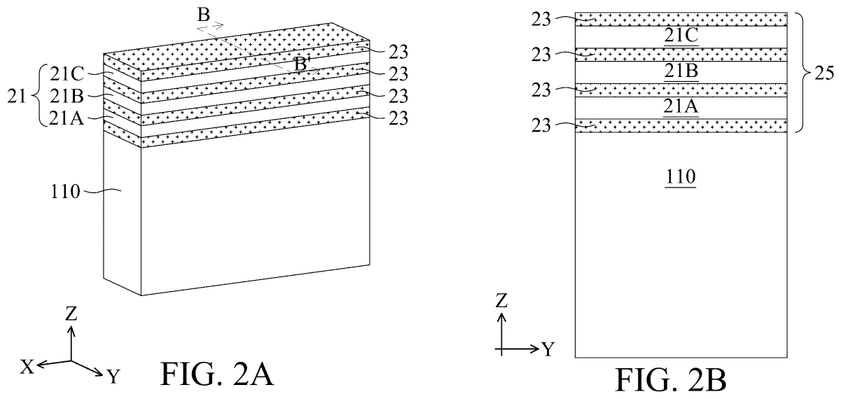

FIGS. 1A and 1B illustrate diagrammatic cross-sectional side views of a portion of a nanostructure device 10, which may be an integrated circuit (IC) device 10 in accordance with various embodiments. FIG. 1A illustrates a view in an X-Z plane. FIG. 2A illustrates a view in a Y-Z plane. The nanostructure device 10 of FIGS. 1A and 1B is described in detail below to provide context for understanding the technical features and benefits of the various embodiments depicted in FIGS. 2A-23.

The nanostructure device 10 includes source/drain regions (or “source/drains”) 82P that include high Ge concentration semiconductor material to improve strain of nanostructure channels 22 adjacent thereto. Although the nanostructure device 10 is described with reference to nanosheet transistors or “nanostructure device” 20A, it should be understood that the embodiments may also include planar field effect transistors (FETs), fin-type FETs (or FinFETs), or the like, each of which may include source/drain regions as will be described with reference to FIGS. 2A-23.

Referring to FIG. 1A, device 10 may be or include one or more N-type FETs (NFETs) or P-type FETs (PFETs). The nanostructure device 20A is formed over and/or in a substrate 110, and generally includes a gate structure 200 straddling and/or wrapping around semiconductor channels 22A, 22B, 22C, alternately referred to as “nanostructures,” located over a semiconductor fin 32 protruding from, and separated by, isolation structures 36 (see FIG. 1B). The gate structure 200 controls electrical current flow through the channels 22A, 22B, 22C between the source/drains 82P on either side thereof.

The nanostructure device 20A is shown including three channels 22A, 22B, 22C, which are laterally abutted by source/drain features 82P and covered and surrounded by the gate structure 200. Generally, the number of channels 22 is two or more, such as three or four or more. In some embodiments, the channels 22A are stacked over the respective fins 32 and channels above the channel 22A (e.g., the channels 22B, 22C) are omitted, corresponding to the number of channels 22 per transistor (e.g., the nanostructure device 20A) being one. The gate structure 200 controls flow of electrical current through the channels 22A, 22B, 22C to and from the source/drain features 82P based on voltages applied at the gate structure 200 and at the source/drain features 82P.

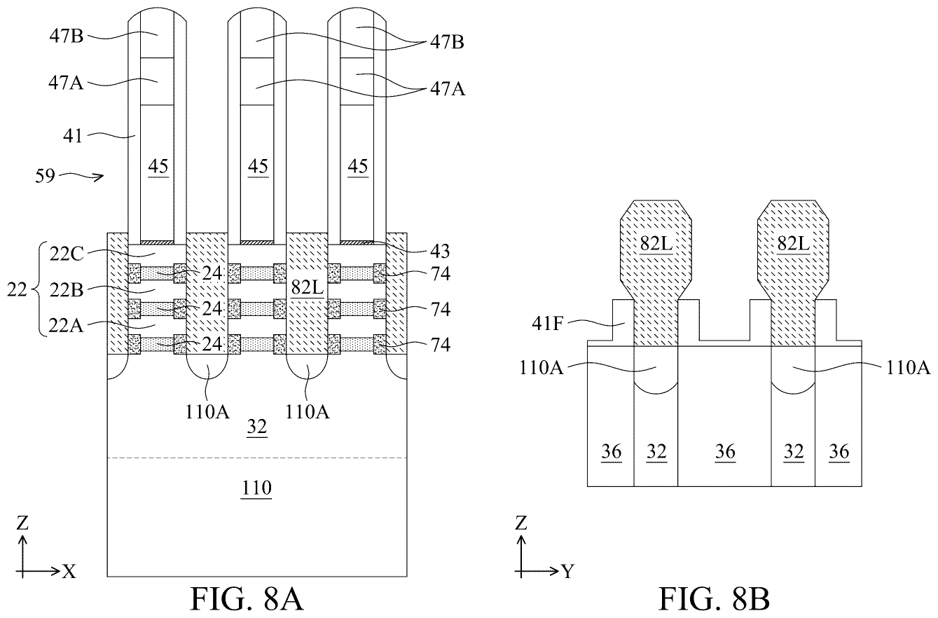

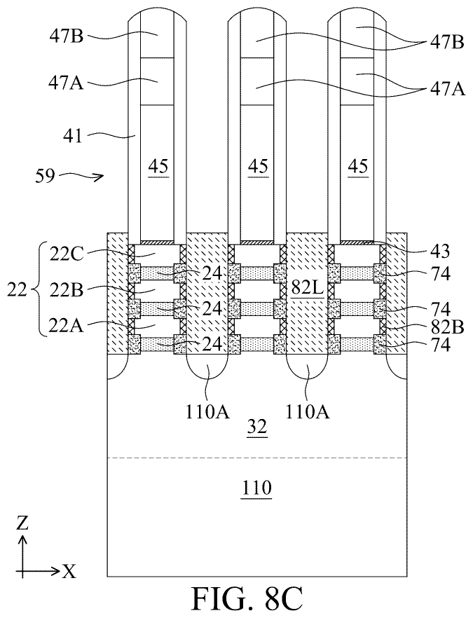

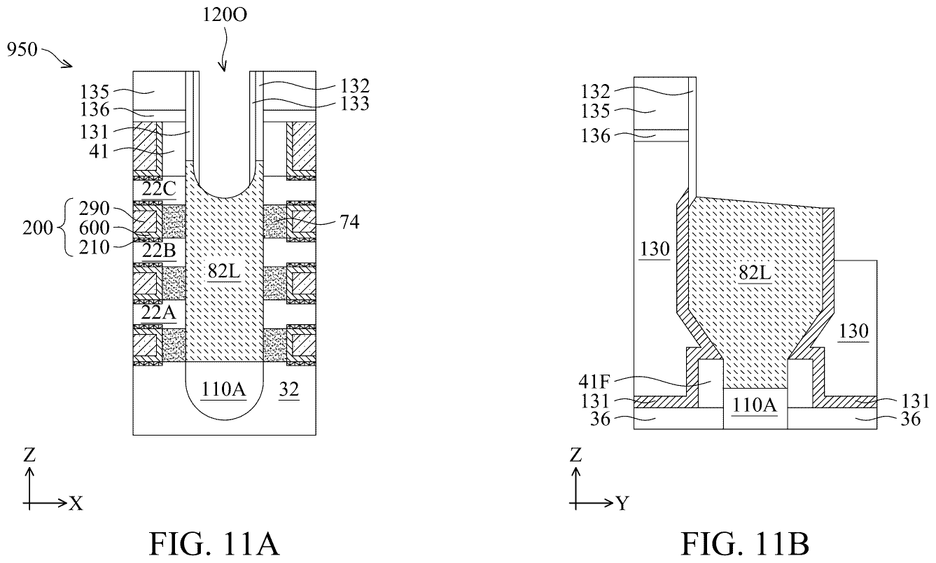

In some embodiments, the fin structure 32 includes silicon. In some embodiments, the nanostructure device 20A includes a PFET, and the source/drain features 82P thereof include silicon germanium (SiGe), Ge, GeSn, SiGeSn or the like, which may be undoped or doped to form, for example, SiGe:B, SiGe:B:Ga, SiGe:Sn, SiGe:B:Sn, or another appropriate semiconductor material. Generally, the source/drain features 82P may include any combination of appropriate semiconductor material(s) and appropriate dopant(s). In some embodiments, the source/drain features 82P include SiₓC_{y}, SiₓGe_{y},SiₓSb_{y}, SiₓP_{y}, SiₓAs_{y}, where 0<x<1 and 0<y<1, as appropriate. The source/drain features 82P may be replacement source/drains 82P which are formed via a process that removes a sacrificial source/drain 82L (FIGS. 8A-8C), then forms the replacement source/drain 82P. Processes for forming the replacement source/drain 82P are described in greater detail with reference to FIGS. 11A-22B.

The channels 22A, 22B, 22C each include a semiconductive material, for example silicon or germanium, or can include a silicon compound or alloy, such as SiGe, SiGeSn, GeSn, or the like. The channels 22A, 22B, 22C are nanostructures (e.g., having at least one dimension that is in a range of 0.1 nm to 10 nm) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

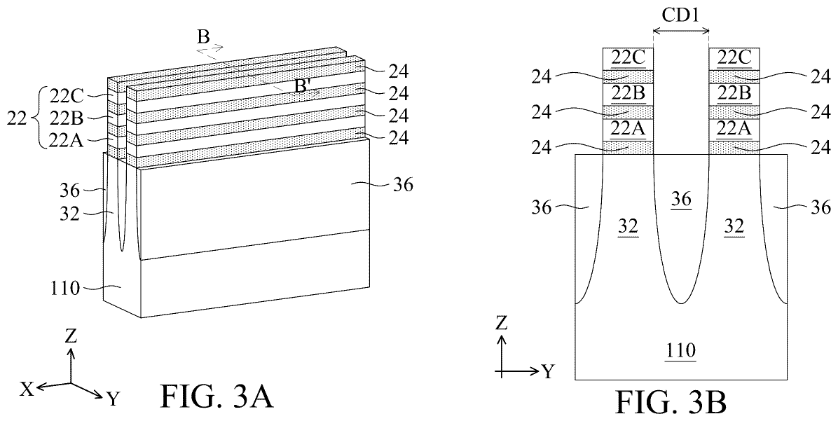

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape and is depicted in FIG. 1A.

In some embodiments, the spacing between the channels 22A, 22B, 22C (e.g., between the channel 22B and the channel 22A or the channel 22C) along the vertical direction (e.g., the Z-axis direction) is in a range between about 8 nanometers (nm) and about 12 nm, though ranges exceeding or below the said range may also be beneficial. In some embodiments, a thickness (e.g., measured in the Z-direction) of each of the channels 22A, 22B, 22C is in a range between about 5 nm and about 8 nm, though ranges exceeding or below the said range may also be beneficial. In some embodiments, a width (e.g., measured in the Y-direction, shown in FIG. 1B, orthogonal to the X-Z plane) of each of the channels 22A, 22B, 22C is at least about 8 nm, however the width may be less than 8 nm in some embodiments.

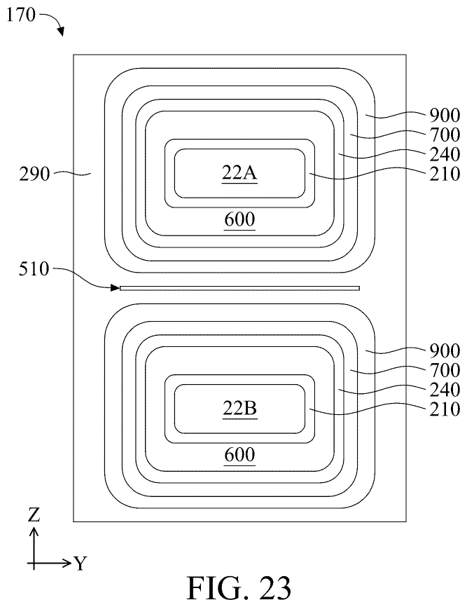

The gate structure 200 is disposed over and between the channels 22A, 22B, 22C, respectively. In some embodiments, the gate structure 200 is disposed over and between the channels 22A, 22B, 22C, which are silicon channels for N-type devices or silicon germanium channels for P-type devices. In some embodiments, the gate structure 200 includes an interfacial layer (IL) 210, one or more gate dielectric layers 600 on the interfacial layer 210, optionally one or more work function tuning layers 900 (see FIG. 23) on the gate dielectric layer 600 and a metal core layer 290 on the gate dielectric layer 600 and optionally on the work function tuning layer 900.

The interfacial layer 210, which may be an oxide of the material of the channels 22A, 22B, 22C, is formed on exposed areas of the channels 22A, 22B, 22C and the top surface of the fin 32. The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k˜3.9). Example high-k dielectric materials include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal layer 290. The metal layer 290 may include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal layer 290 is surrounded (in the cross-sectional view) by the one or more work function metal layers 900, which are then surrounded by the gate dielectric layers 600, which are surrounded by the interfacial layer 210. The gate structure 200 may also include a glue layer that is formed between the one or more work function layers 900 and the metal layer 290 to increase adhesion. The glue layer is not specifically illustrated in FIG. 1A for simplicity.

The nanostructure device 20A may further include source/drain contacts 120 that are formed over the source/drain features 82P. The source/drain contacts 120 may include a conductive layer that is or includes a conductive material such as tungsten, ruthenium, cobalt, copper, titanium, titanium nitride, tantalum, tantalum nitride, iridium, molybdenum, nickel, aluminum, or combinations thereof. The conductive layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm.

Silicide layers 118 are positioned between the source/drain features 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22.

Referring to FIG. 1B, the nanostructure device 20A may further include an interlayer dielectric (ILD) 130. The ILD 130 provides electrical isolation between the various components of the nanostructure device 20A discussed above, for example between neighboring pairs of the source/drain contacts 120. An etch stop layer 131 may be formed prior to forming the ILD 130 and may be positioned laterally between the ILD 130 and the gate spacers 41 and vertically between the ILD 130 and the source/drain features 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

Additional ILD layer 135, additional etch stop layer 136 and protection layer 132 may be present on upper and/or side surfaces of the gate structures 200 and the gate spacers 41. The additional ILD layer 135 may be similar in most respects to the ILD 130. The additional etch stop layer 136 and protection layer 132 may be similar in most respects to the etch stop layer 131. A cover layer 133, which is a dielectric layer (e.g., formed of SiON) may be present between the source/drain contact 120 and the etch stop layer 131 and the protection layer 132. The cover layer 133 may extend to a level that is below a bottom surface of the etch stop layer 131, as depicted in FIG. 1A.

The nanostructure device 20A includes gate spacers 41 that are disposed on sidewalls of the metal layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are also disposed between the channels 22A, 22B, 22C. In some embodiments, the gate spacers 41 include a multilayer, such as a bilayer including first and second spacer layers. The first and second spacer layers may each include a dielectric material, for example a low-k material such as SiOCN, SiON, SIN, SiCN, SiOC or the like. In some embodiments, the second spacer layer is not present. Material of the first and second spacer layers may be the same as or different from each other. In some embodiments, an upper portion of the second spacer layer (or the first spacer layer when the second spacer layer is not present) may be removed partially or fully to increase aspect ratio of an opening through which the source/drain region 82P is formed. FIG. 1A depicts an embodiment in which the upper portion of the gate spacer 41 is not thinned.

FIG. 1A depicts p-type source/drains 82P that are associated with the nanostructure device 20A that is a PFET. In some embodiments, the device 10 includes additional nanostructure devices that are NFETs. Although not depicted, the NFETs may have n-type source/drains that are or include a different material than the PFETs. For example, the source/drains 82P of the PFETs may be replacement source/drains 82P and the source/drains of the NFETs may not be replacement source/drains. Namely, the replacement source/drains 82P may have germanium concentration that exceeds that of source/drains of the NFETs.

In FIG. 1A, recess source/drain portions 82B may be positioned between the source/drain 82P and adjacent channels 22. In some embodiments, the recess source/drain portions 82B are or include SiB.

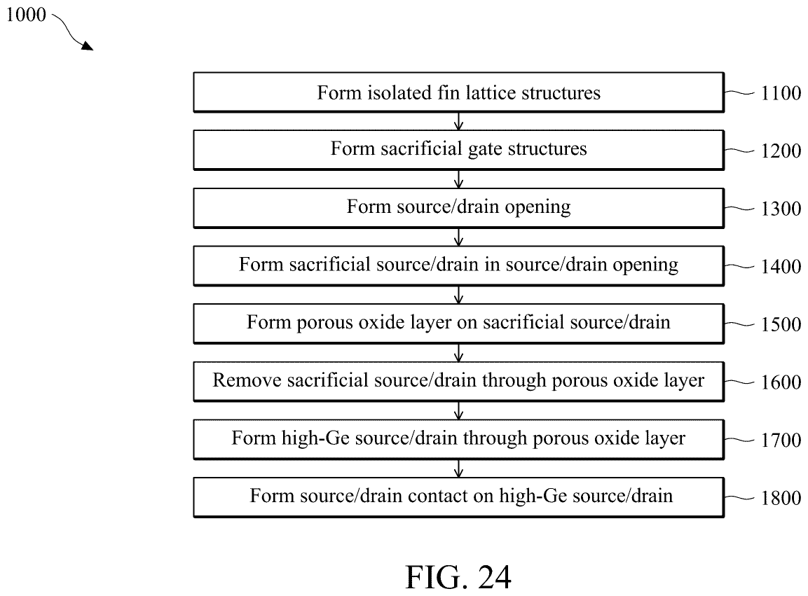

FIG. 24 depicts a flowchart of a method 1000 for forming an IC device or a portion thereof from a workpiece, according to one or more aspects of the present disclosure. Method 1000 is merely an example and not intended to limit the present disclosure to what is explicitly illustrated in method 1000. Additional acts can be provided before, during and after the method 1000 and some acts described can be replaced, eliminated, or moved around for additional embodiments of the method. Not all acts are described herein in detail for reasons of simplicity. Method 1000 is described below in conjunction with fragmentary perspective and/or cross-sectional views of a workpiece, shown in FIGS. 2A-23, at different stages of fabrication according to embodiments of method 1000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

FIGS. 2A through 23 are views of intermediate stages in the manufacturing of FETs, such as nanostructure FETs, in accordance with some embodiments.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23. In some embodiments, the first semiconductor layers 21 may be or include a first semiconductor material such as silicon, silicon carbide, germanium, SiGe, GeSn, SiGeSn or the like, and the second semiconductor layers 23 may be formed of a second semiconductor material that has different etch selectivity than the first semiconductor material. In most embodiments, the second semiconductor material is silicon germanium. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like.

Three layers of the first semiconductor layers 21 and four layers of the second semiconductor layers 23 are illustrated. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21. Although the multi-layer stack 25 is illustrated as including a second semiconductor layer 23 as the topmost layer, in some embodiments, the uppermost layer of the multi-layer stack 25 may be a first semiconductor layer 21.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIG. 24. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures or “interposers” 24 are formed from the second semiconductor layers 23. Distance CD1 between adjacent fins 32 and nanostructures 22, 24 may be from about 18 nm to about 100 nm, though distances CD1 that are smaller than 18 nm may be beneficial in some embodiments. A portion of the device 10 is illustrated in FIGS. 3A and 3B including two fins 32 for simplicity of illustration. The process 1000 illustrated in FIG. 24 may be extended to any number of fins, and is not limited to the two fins 32 shown in FIGS. 3A-23.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIG. 3A and 3B, isolation regions or features 36, which may be shallow trench isolation (STI) regions or features, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

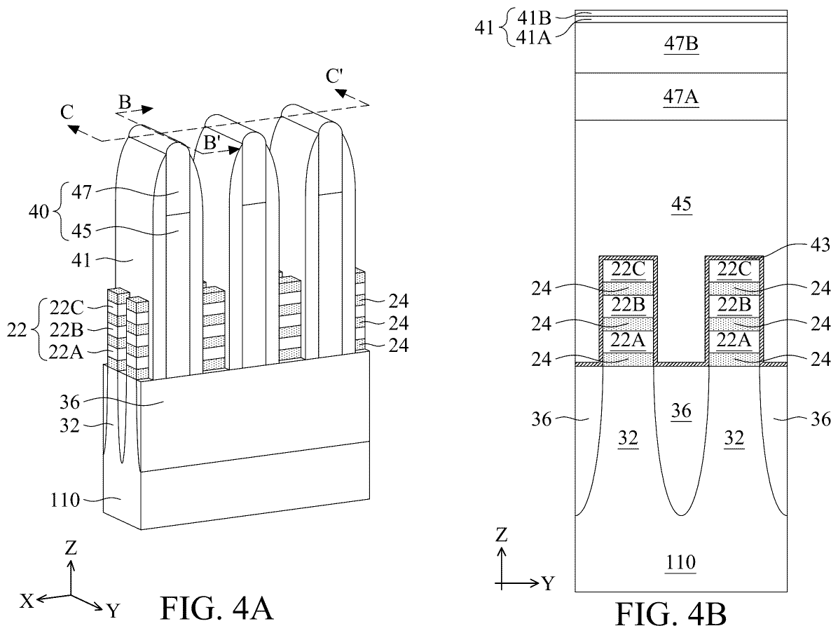

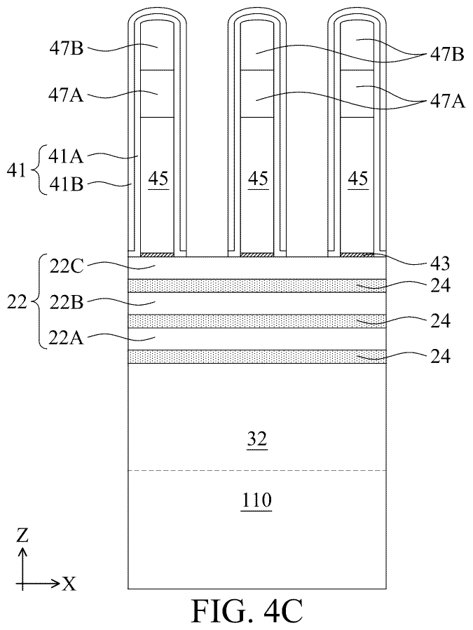

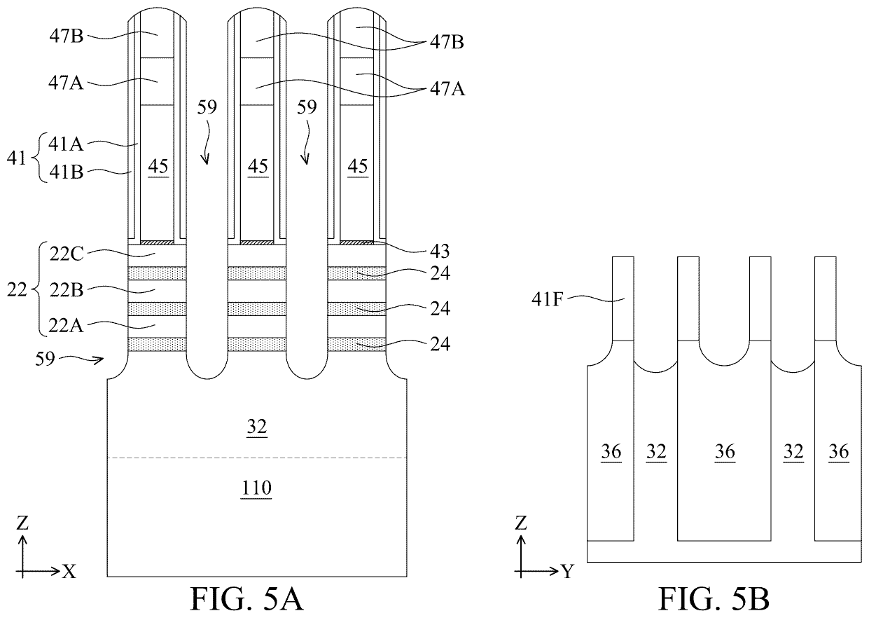

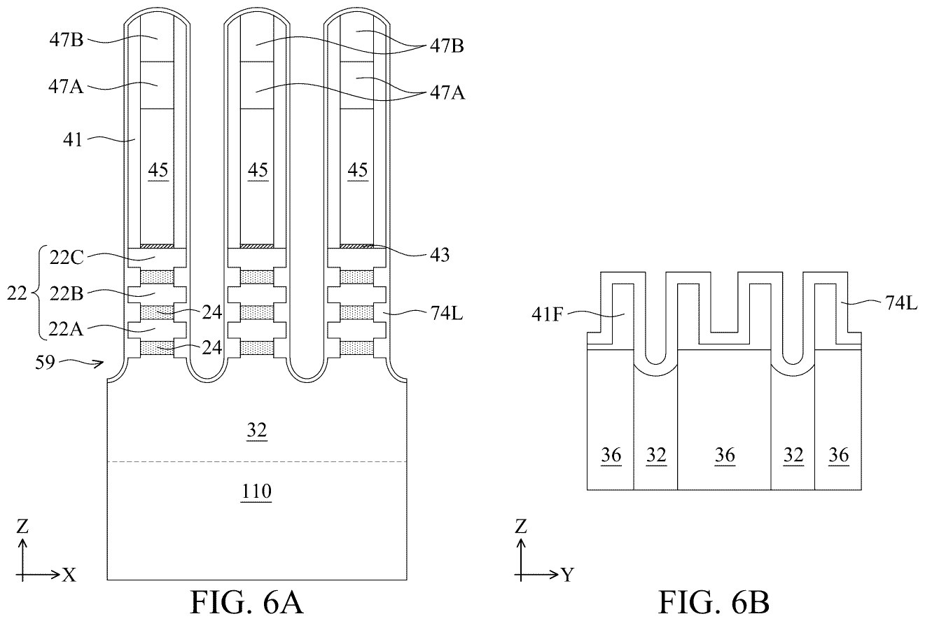

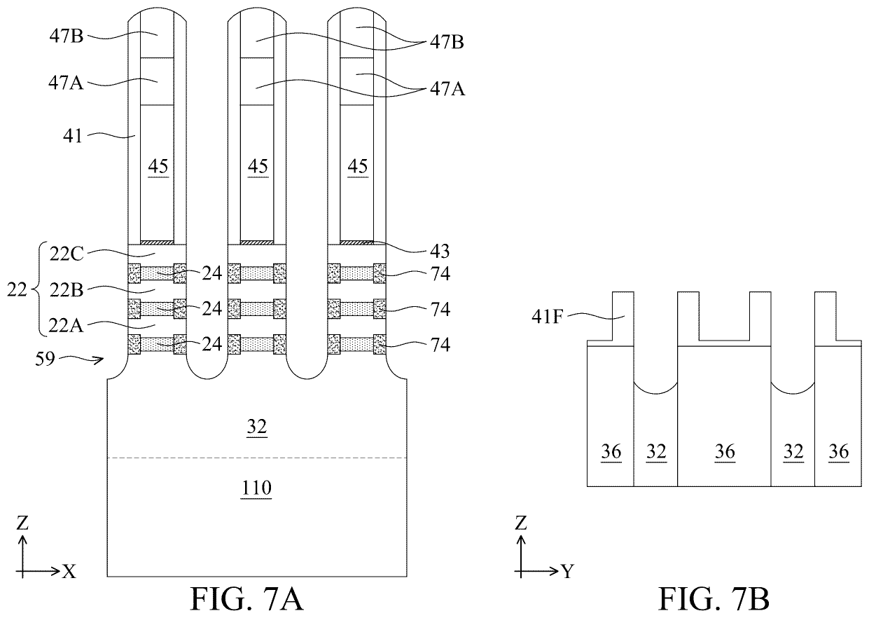

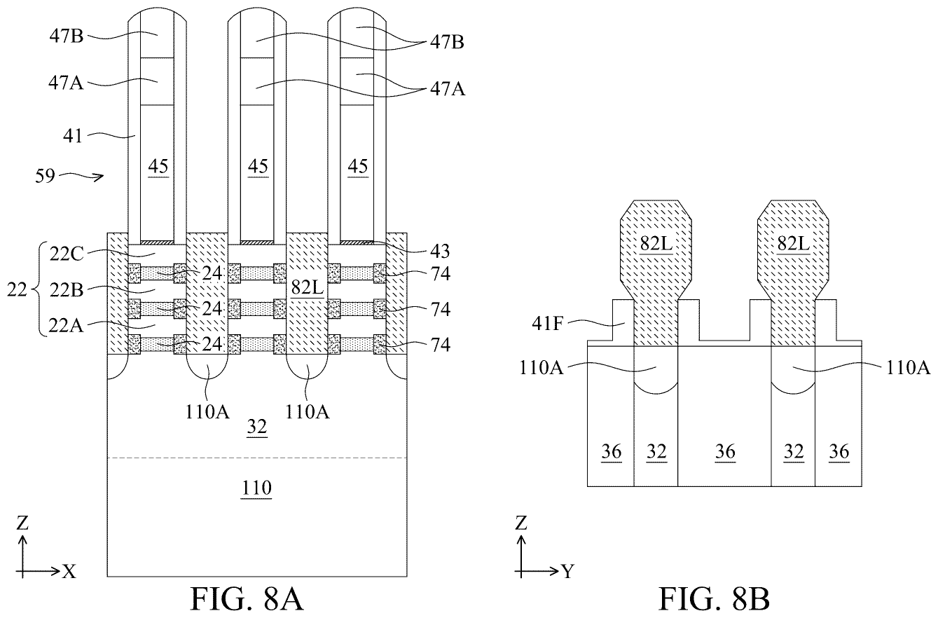

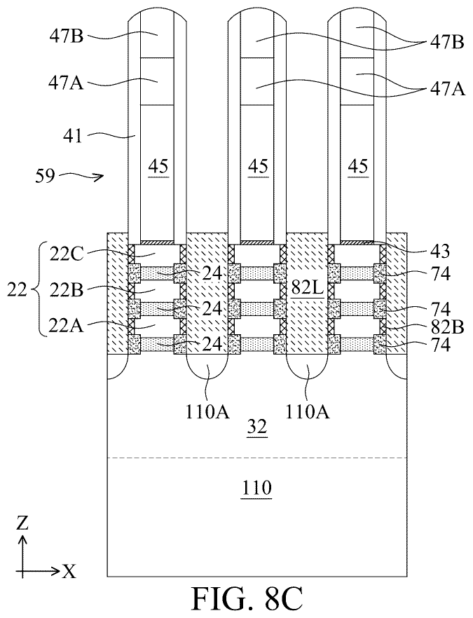

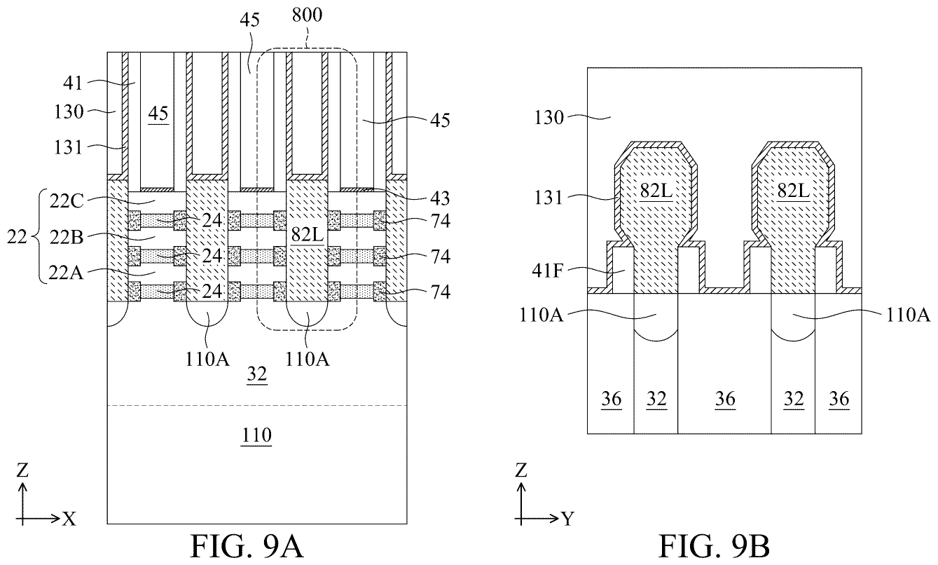

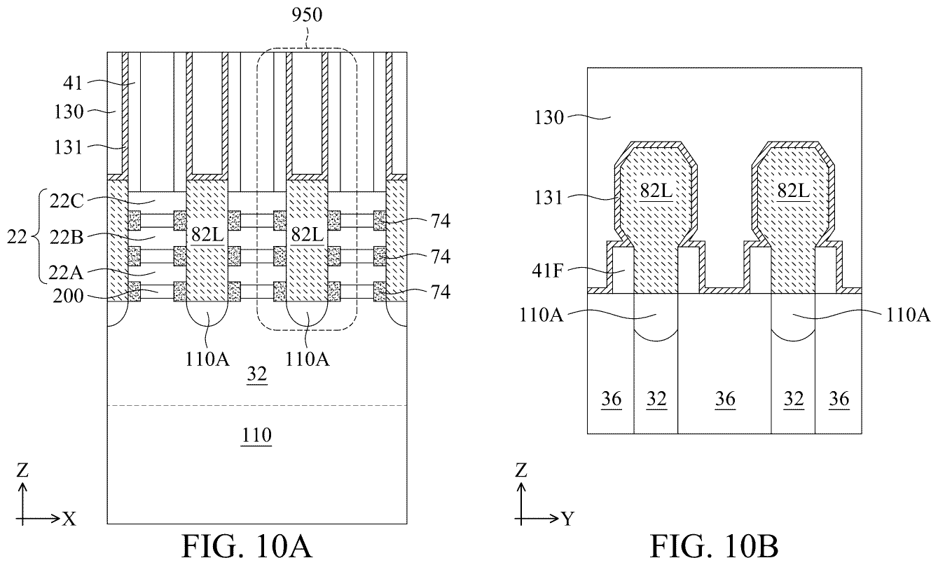

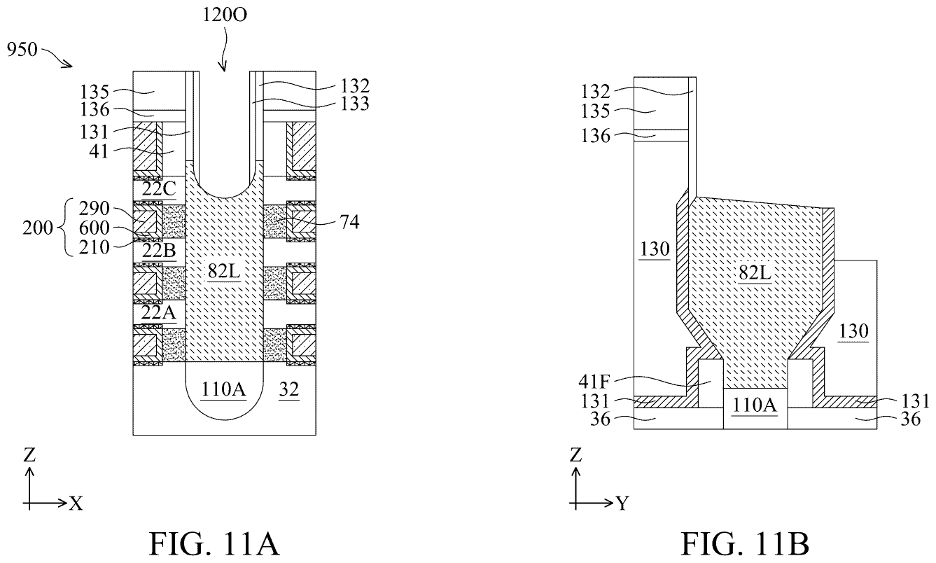

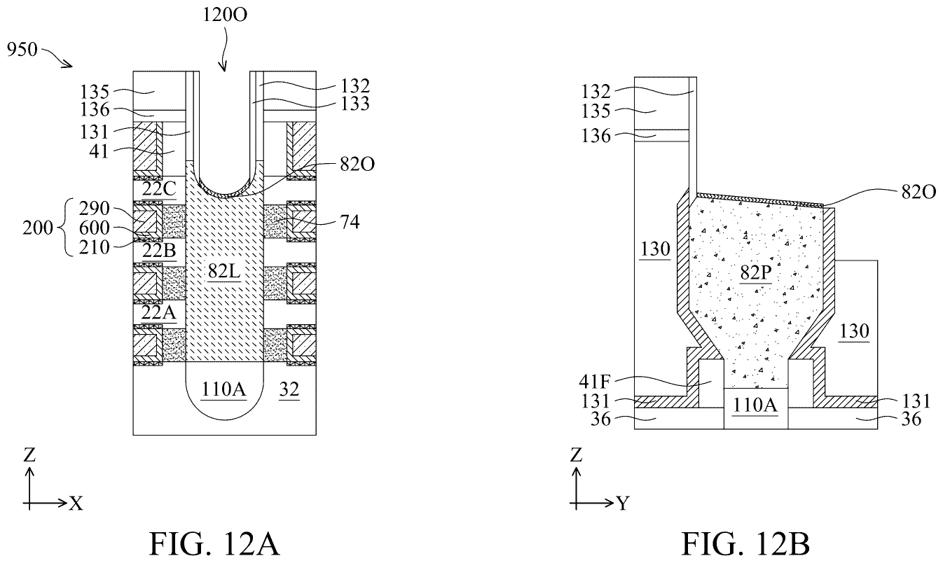

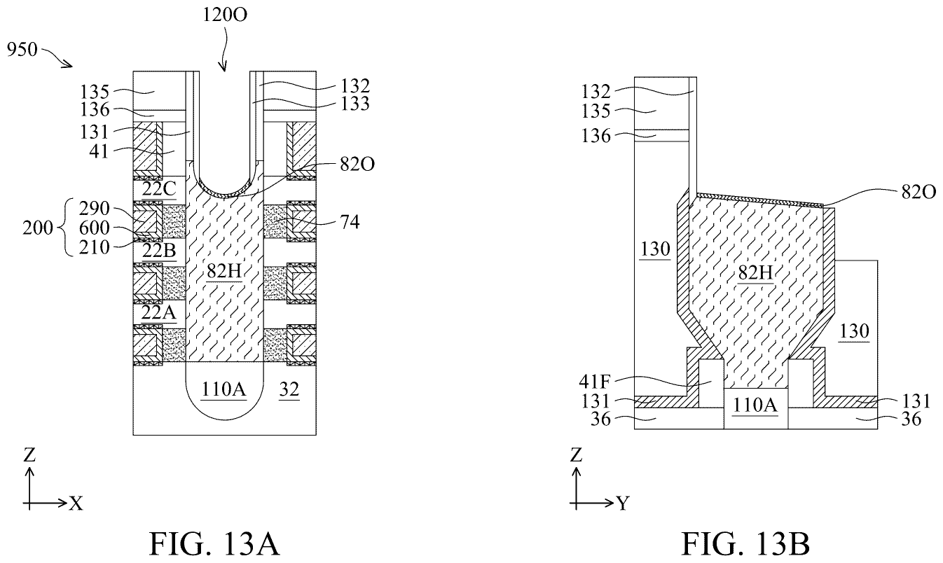

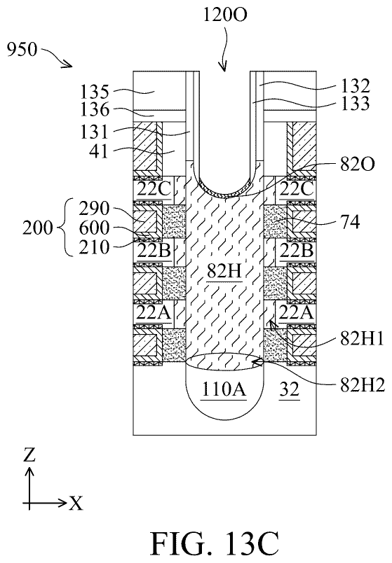

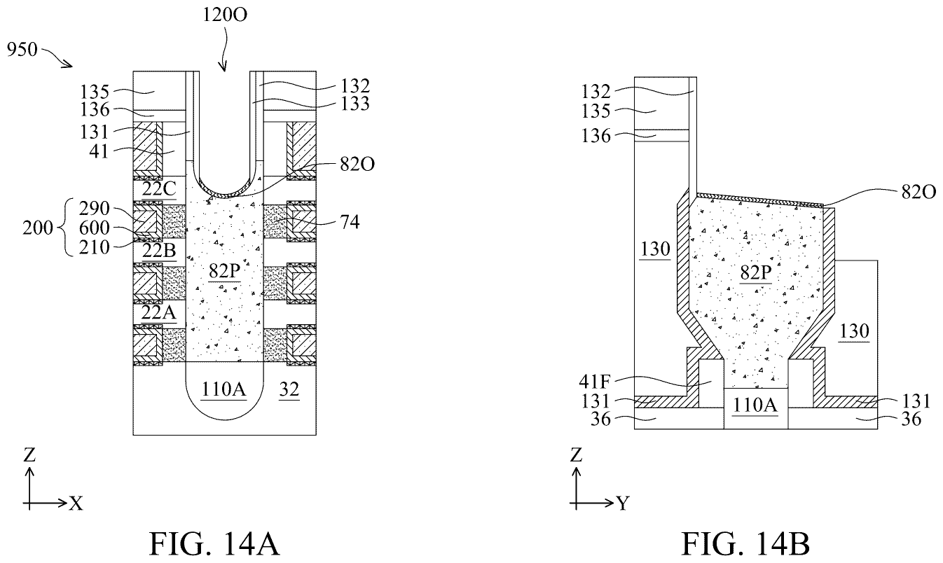

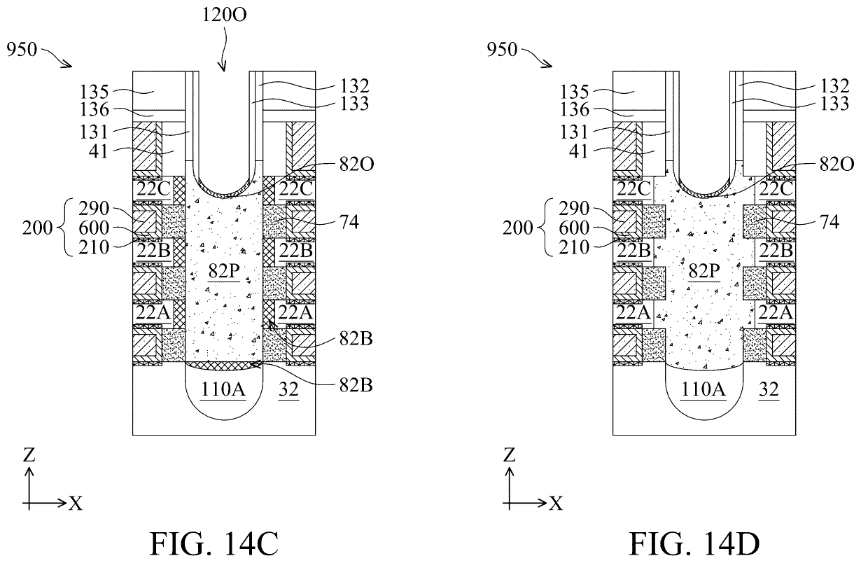

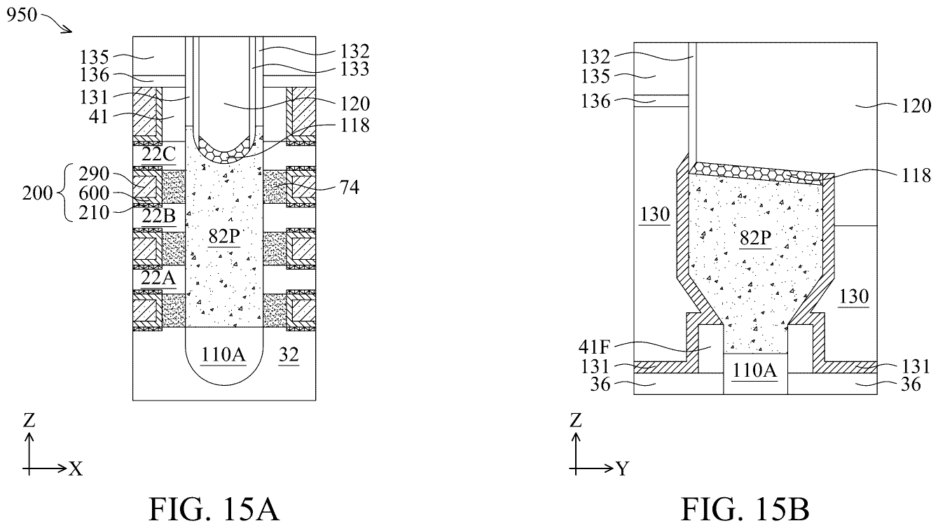

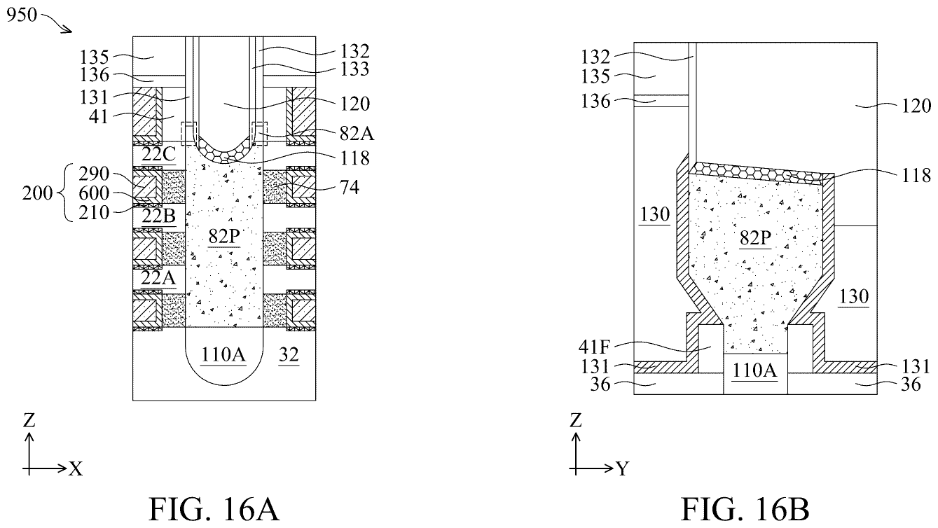

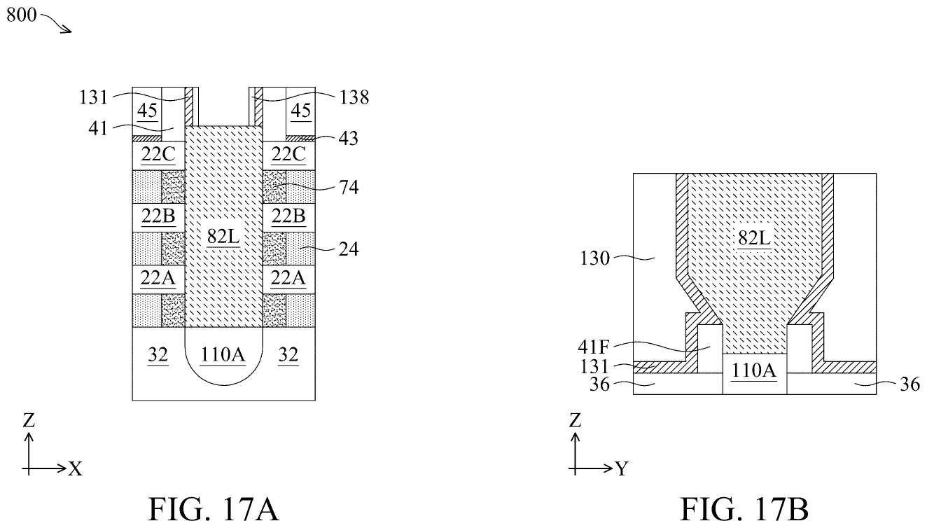

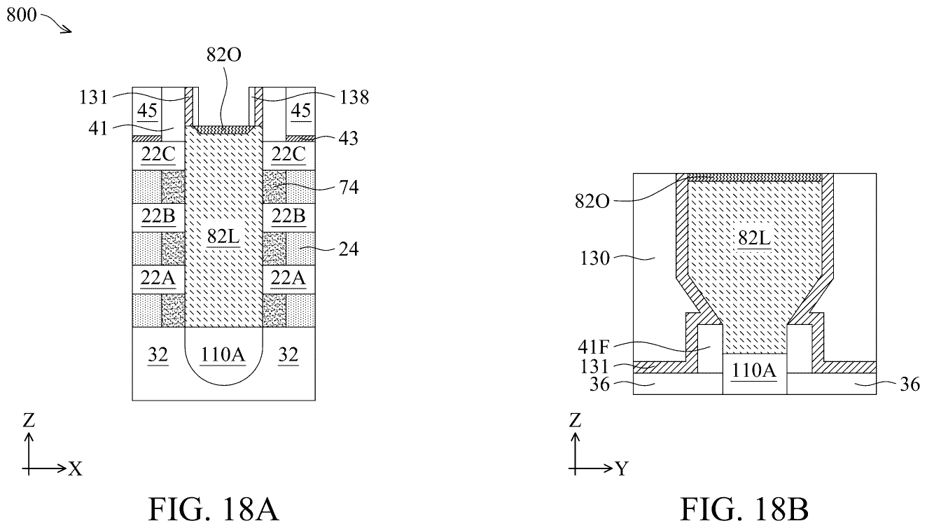

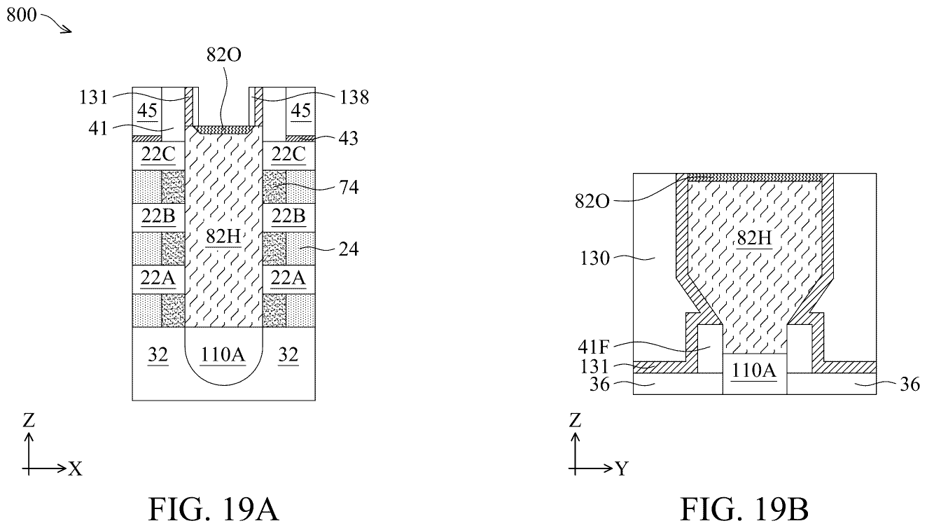

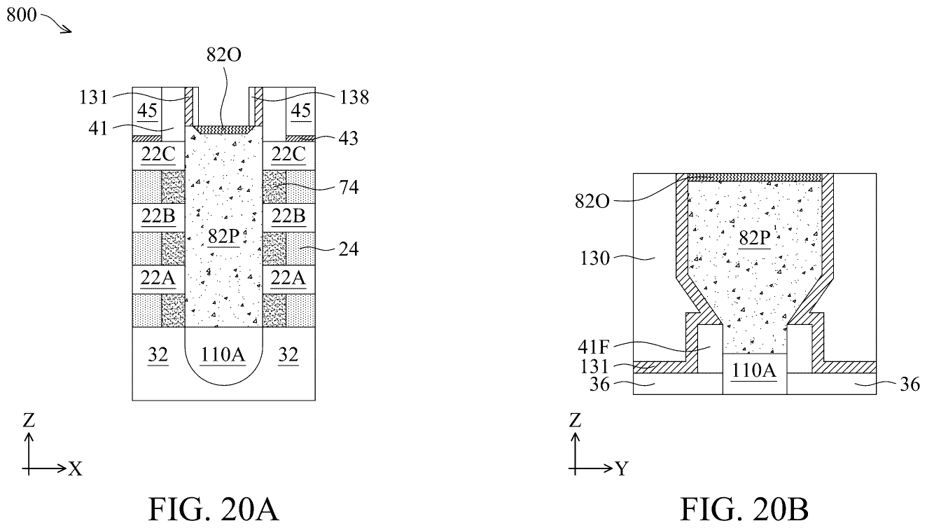

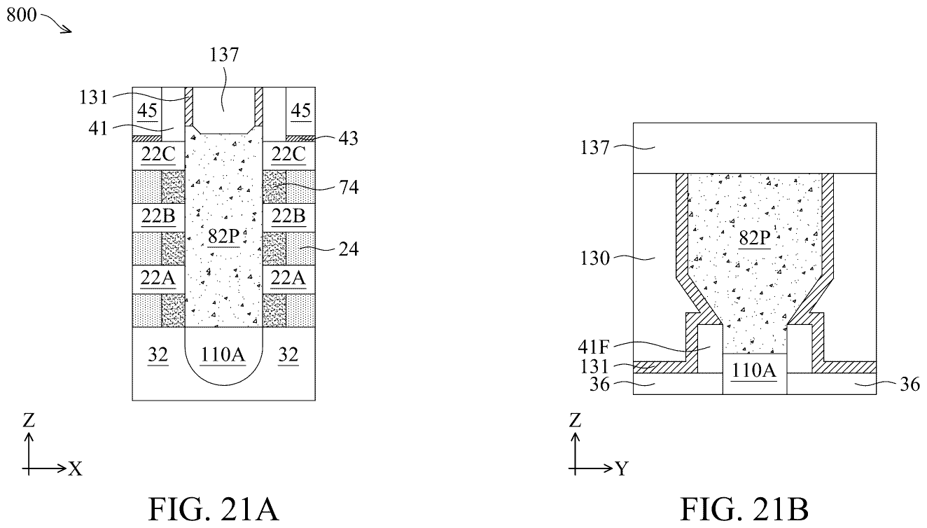

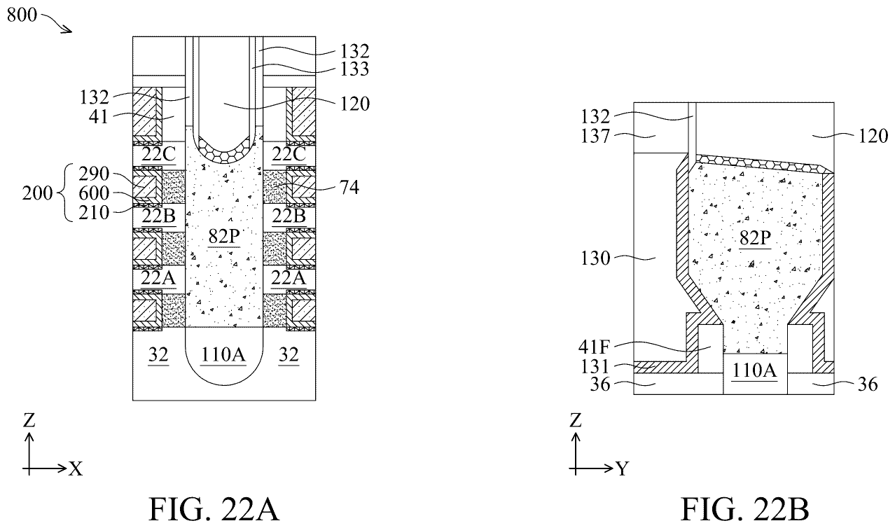

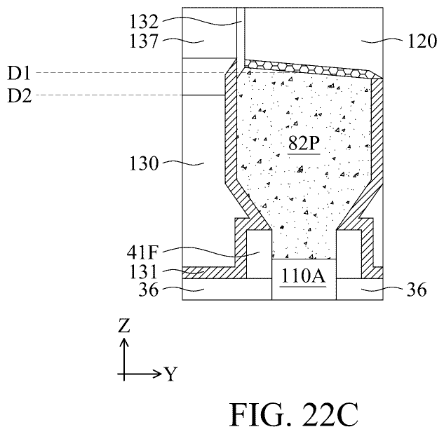

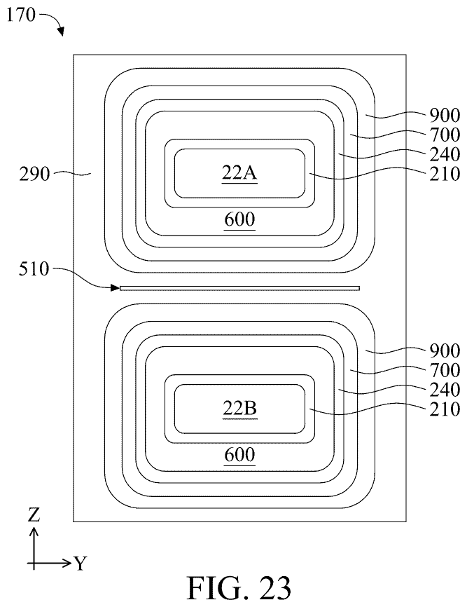

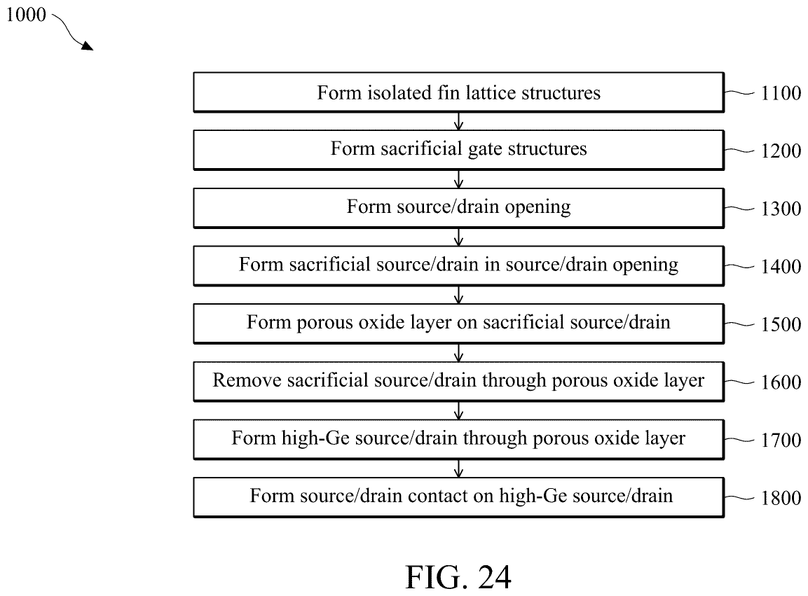

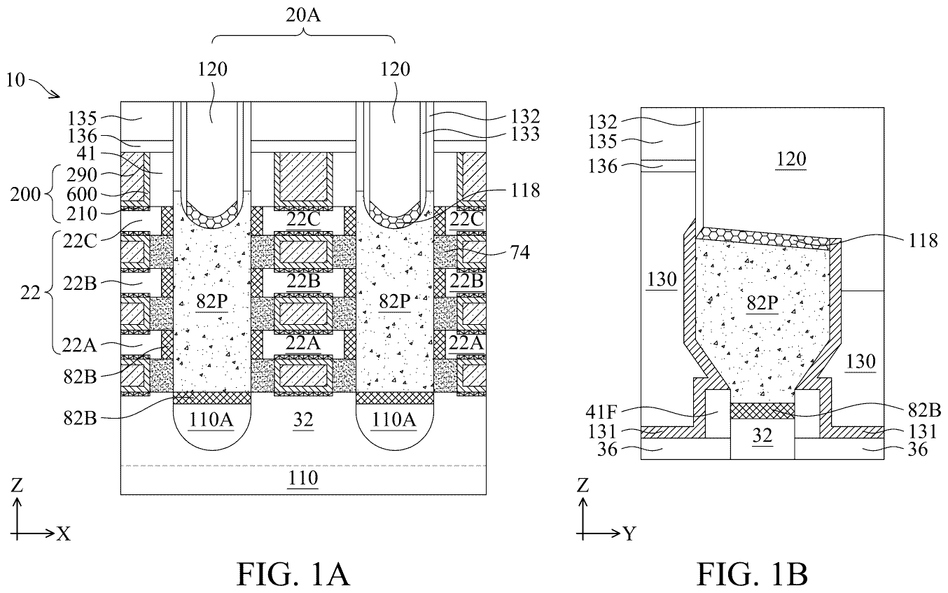

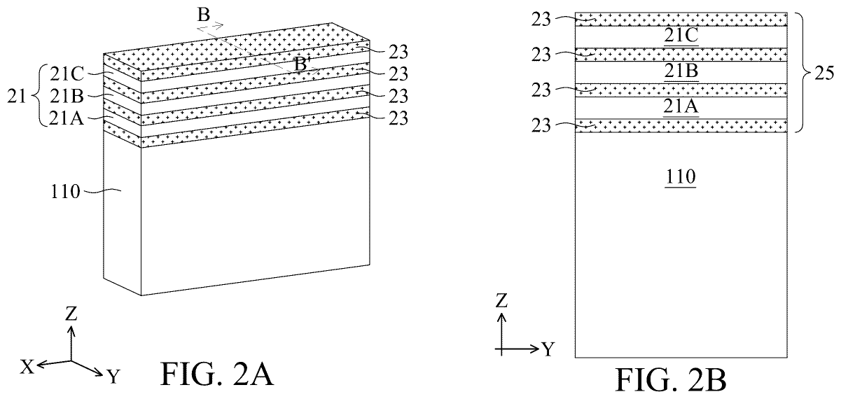

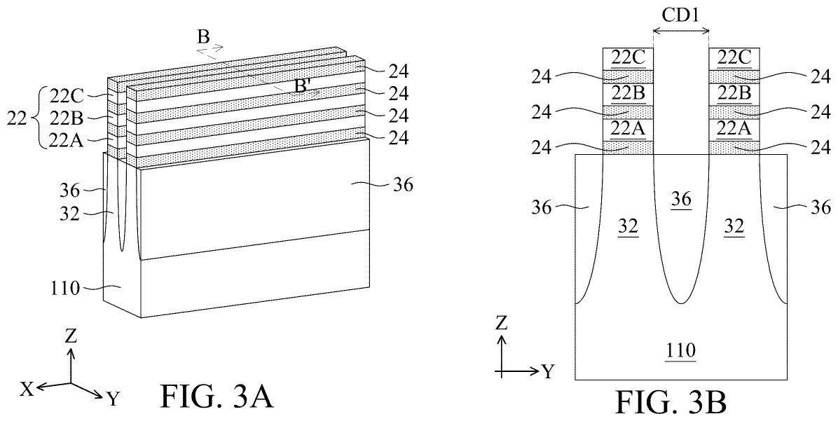

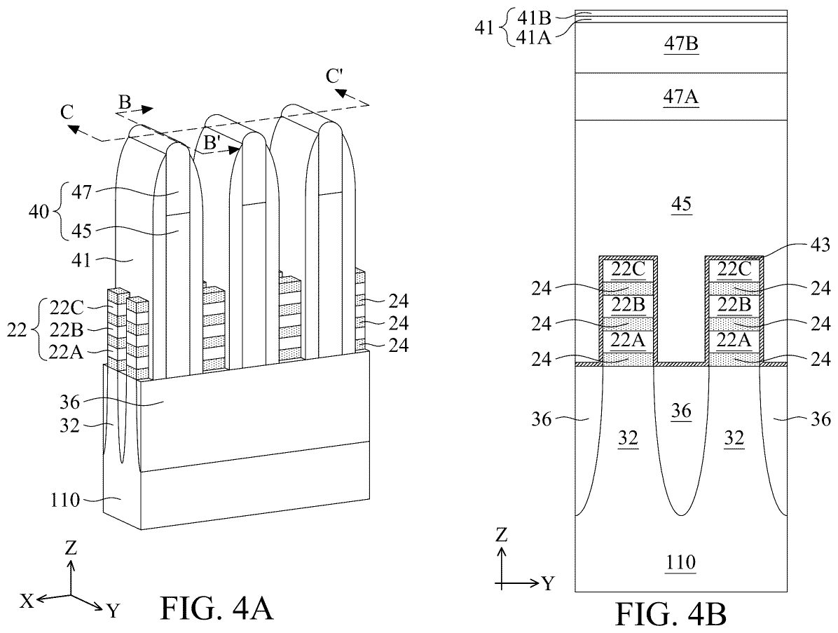

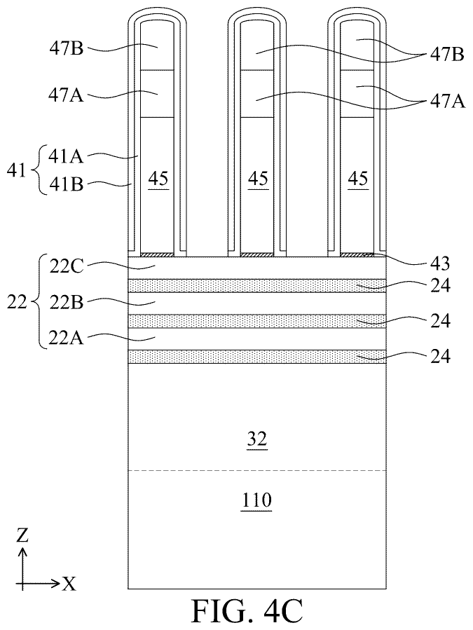

In FIGS. 4A-4C, dummy or sacrificial gate structures 40 are formed over the fins 32 and/or the nanostructures 22, 24, corresponding to act 1200 of FIG. 24. A dummy or sacrificial gate layer 45 is formed over the fins 32 and/or the nanostructures 22, 24. The sacrificial gate layer 45 may be or include materials that have a high etching selectivity relative to the isolation regions 36. The sacrificial gate layer 45 may be a conductive, semiconductive or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 45 may be deposited by physical vapor deposition (PVD), CVD, sputter deposition, or other techniques for depositing the selected material. A mask layer 47 is formed over the sacrificial gate layer 45, and may include, for example, silicon nitride, silicon oxynitride, or the like. In some embodiments, a gate dielectric layer 43 is formed before the sacrificial gate layer 45 between the sacrificial gate layer 45 and the fins 32 and/or the nanostructures 22, 24. In some embodiments, the mask layer 47 includes a first mask layer 47A in contact with the sacrificial gate layer 45, and a second mask layer 47B overlying and in contact with the first mask layer 47A. The first mask layer 47A may be or include the same or different material as that of the second mask layer 47B.

A spacer layer 41 is formed over sidewalls of the mask layer 47 and the sacrificial gate layer 45. The spacer layer 41 is or includes an insulating material, such as SiOCN, SiOC, SiCN or the like (or any of the materials described with reference to FIG. 1A) and may have a single-layer structure or a multi-layer structure including a plurality of dielectric layers, in accordance with some embodiments. The spacer layer 41 may be formed by depositing a spacer material layer (not shown) over the mask layer 47 and the sacrificial gate layer 45. Portions of the spacer material layer between sacrificial gate structures 40 are removed using an anisotropic etching process, in accordance with some embodiments. In some embodiments, as shown in detail in FIGS. 4B and 4C, the spacer layer 41 includes a first spacer layer 41A in contact with the nanostructure 22C, the gate dielectric layer 43, the sacrificial gate layer 45 and the first and second mask layers 47A, 47B. A second spacer layer 41B of the spacer layer 41 may be in contact with the first spacer layer 41A. The first spacer layer 41A may be or include the same or different material as that of the second spacer layer 41B.

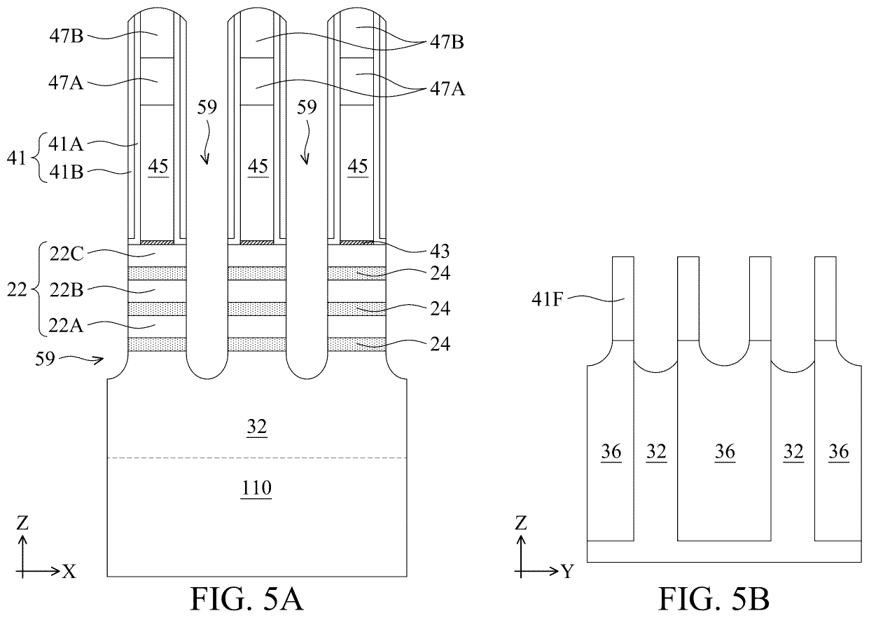

In FIGS. 5A and 5B, source/drain openings 59 are formed by performing an etching process to etch the portions of protruding fins 32 and/or nanostructures 22, 24 that are not covered by sacrificial gate structures 40, corresponding to act 1300 of FIG. 24. The recessing may be anisotropic, such that the portions of fins 32 directly underlying sacrificial gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. FIG. 5A depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layers 41A, 41B during the etching process. FIG. 5B depicts fin spacers 41F which are portions of the first and/or second spacer layers 41A, 41B that overlie the isolation regions 36 adjacent to respective fins 32.

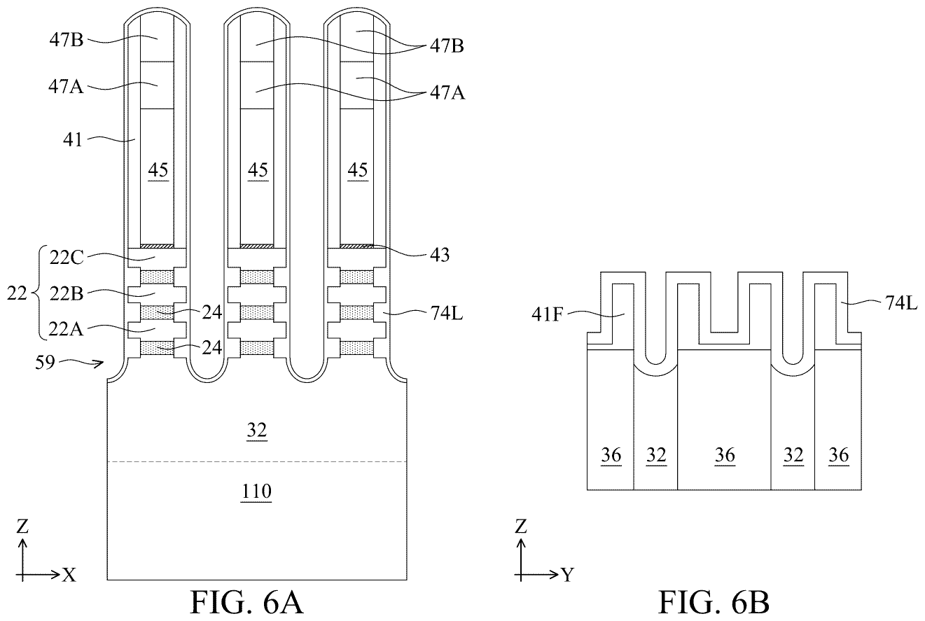

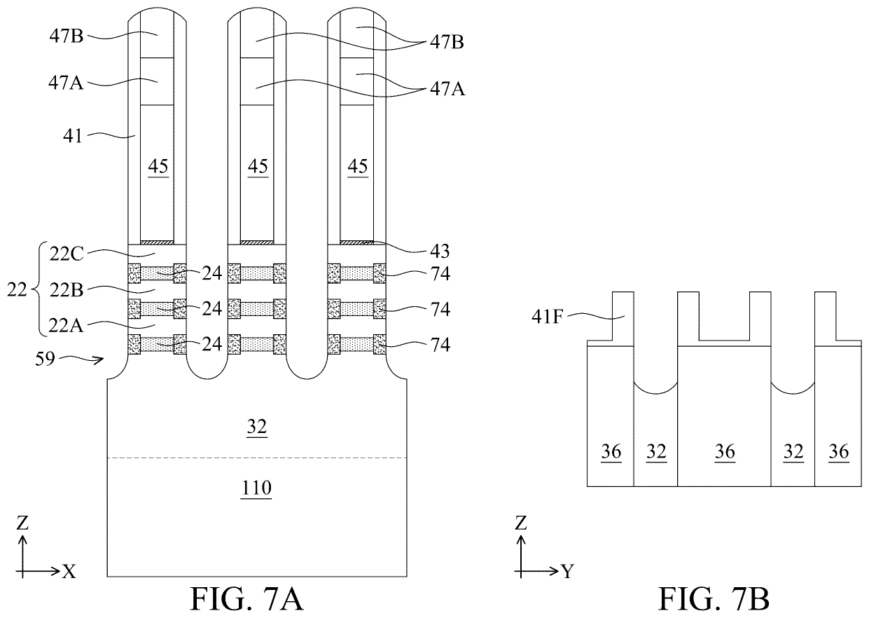

FIGS. 6A-7B depict formation of inner spacers 74 in accordance with various embodiments.

In FIGS. 6A, 6B, a selective etching process is performed to recess end portions of the nanostructures 24 exposed by openings in the spacer layer 41 without substantially attacking the nanostructures 22. After the selective etching process, recesses are formed in the nanostructures 24 at locations where the removed end portions used to be. Then, following formation of the recesses, an inner spacer layer 74L is formed to fill (partially or entirely) the recesses in the nanostructures 22 formed by the previous selective etching process. The inner spacer layer 74L may be a suitable dielectric material, such as silicon carbon nitride (SiCN), silicon oxycarbonitride (SiOCN), or the like, formed by a suitable deposition method such as PVD, CVD, ALD, or the like.

In FIGS. 7A and 7B, following formation of the inner spacer layer 74L, an etching process, such as an anisotropic etching process, is performed to remove portions of the inner spacer layer 74 disposed outside the recesses, for example, to remove portions of the inner spacer layer 74 on sidewalls of the nanostructures 22 and the fins 32. The remaining portions of the inner spacer layer 74L (e.g., portions disposed inside the recesses in the nanostructures 24) form the inner spacers 74. The resulting structure is shown in FIG. 7A.

In FIGS. 8A, 8B, a first material layer 110A is formed in the source/drain openings 59. The first material layer 110A may be or include an undoped semiconductor, such as undoped silicon. The deposition may include one or more operations, such as a CVD, which may be an ultra-high vacuum CVD (UHV-CVD), which allows for improved control of deposition rate and purity of the first material layer 110A. The first material layer 110A may extend to a level that is at or slightly above an upper surface of the fin 32. In some embodiments, the first material layer 110A is not formed.

Then, source/drain layers 82L associated with p-type nanostructure devices may be epitaxially grown from epitaxial material(s), corresponding to act 1400 of FIG. 24. The source/drain layers 82L may grow from the channels 22 and the undoped silicon layer 110A. The source/drain layers 82L are formed such that each dummy gate structure 40 is disposed between respective neighboring pairs of the source/drain layers 82L. In some embodiments, the spacer layer 41 separates the source/drain layers 82L from the sacrificial gate layer 45 by an appropriate lateral distance to prevent electrical bridging to subsequently formed gates of the resulting device. The source/drain layers 82L may have surfaces raised from respective surfaces of the fins 32 and may have facets, as depicted in FIG. 8B. Neighboring source/drain layers 82L may merge in some embodiments to form a singular source/drain layer 82L adjacent two neighboring fins 32.

In FIG. 8C, in accordance with some embodiments, prior to forming the source/drain layers 82L, end portions of the nanostructures 22 may be recessed, followed by formation of semiconductor layers 82B in the recesses. In at least some embodiments, the end portions of the nanostructures 22 may be recessed during the source/drain formation process. The semiconductor layers 82B may be SiB layers that can be beneficial in preventing damage to the source/drain layers 82L during formation thereof. In subsequent processes in which the source/drain layers 82L are replaced with high Ge % source/drains 82P, the semiconductor layers 82B may remain in the recesses or may be removed during the replacement process.

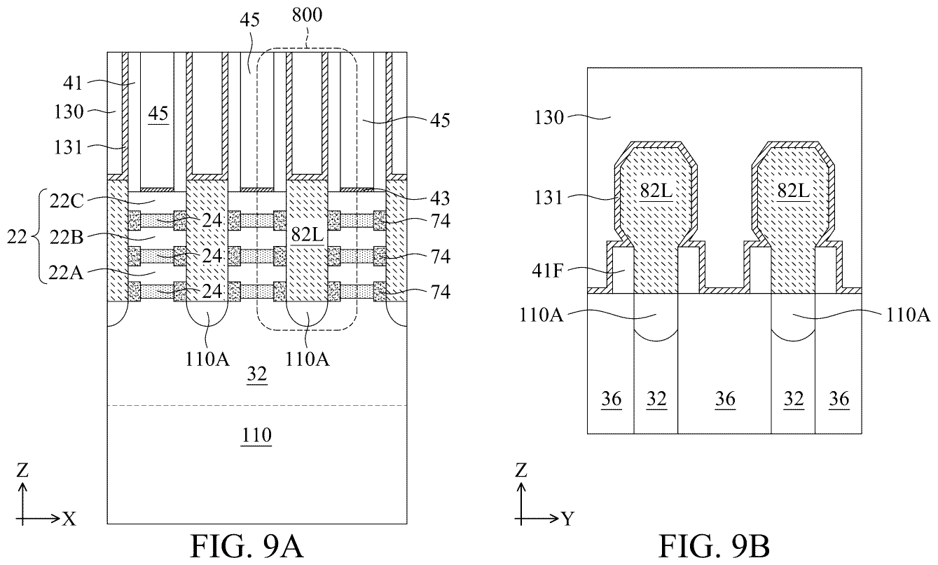

In FIGS. 9A and 9B, following formation of the source/drain layers 82L, the ILD 130 may be formed covering the source/drain layers 82L and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD 130 may be deposited by spin-on coating, CVD, Flowable CVD (FCVD), PECVD, PVD, or another deposition process.

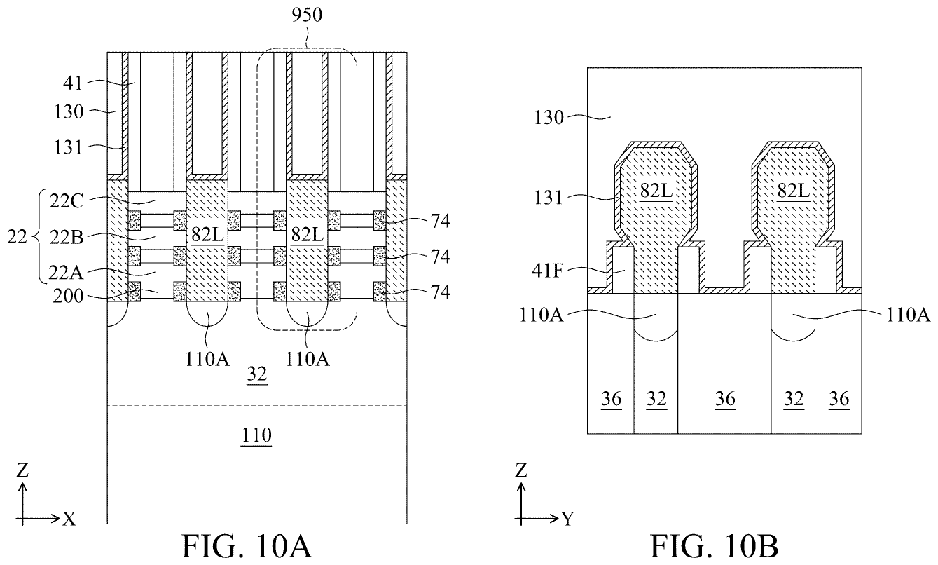

In FIGS. 10A and 10B, following formation of the source/drain layers 82L, the ESL 131 and the ILD 130, active or replacement gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the sacrificial gate layers 45 are exposed. The top surfaces of the ILD 130 and the ESL 131 may be coplanar with the top surfaces of the dummy gate layers 45 and the gate spacers 41.

Then, the sacrificial gate layer 45 is removed in an etching process, so that openings are formed. In some embodiments, the sacrificial gate layer 45 is removed by an anisotropic dry etch process. For example, the etching process may include a dry etch process using reaction gas(es) that selectively etch the dummy gate layer 45 without etching the spacer layer 41. The sacrificial gate dielectric 43, when present, may be used as an etch stop layer when the sacrificial gate layer 45 is etched. The sacrificial gate dielectric 43 may then be removed after the removal of the sacrificial gate layer 45.

The nanostructures 24 are removed to release the nanostructures 22, corresponding to acts 1600 of FIG. 24, respectively. After the nanostructures 24 are removed, the nanostructures 22 form a plurality of nanosheets that extend horizontally (e.g., parallel to a major upper surface of the substrate 110). Removal of the nanostructures 24 may be by one or more selective etching processes that use an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like.

In some embodiments, the nanosheets 22 are reshaped (e.g., thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

In FIGS. 10A and 10B, following release of the channels 22, replacement gates 200 are formed, corresponding to act 1700 of FIG. 24, respectively. The replacement gates 200 may be referred to as active gates 200 or gate structures 200. The gate structures 200 may be formed by a series of deposition operations, such as ALD cycles, that deposit the various layers of the gate structure 200 in the openings, described with reference to FIG. 23.

FIG. 23 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 23, in some embodiments, the first IL 210 includes an oxide of the semiconductor material of the substrate 110, e.g., silicon oxide. In other embodiments, the first IL 210 may include another suitable type of dielectric material. The first IL 210 has a thickness in a range between about 5 angstroms and about 50 angstroms.

Still referring to FIG. 23, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl4 and/or H2O as precursors. Such an ALD process may form the gate dielectric layer 600 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k˜ 3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure device 20A.

With further reference to FIG. 23, the second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200, and serves to limit diffusion of metallic impurity from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In a specific embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 23, after forming the second IL 240 and removing the high-k capping layer, the work function barrier layer 700 is optionally formed on the gate structure 200, in accordance with some embodiments. The work function barrier layer 700 is or comprises a metal nitride, such as TIN, WN, MON, TaN, or the like. In a specific embodiment, the work function barrier layer 700 is TiN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 23 further illustrates the metal layer 290. In some embodiments, a glue layer (not separately illustrated) is formed between the oxygen blocking layer of the work function metal layer and the metal layer 290. The glue layer may promote and/or enhance the adhesion between the metal layer 290 and the work function metal layer 900. In some embodiments, the glue layer may be formed of a metal nitride, such as TiN, TaN, MON, WN, or another suitable material, using ALD. In some embodiments, thickness of the glue layer is between about 10 A and about 25 A. The metal layer 290 may be formed on the glue layer, and may include a conductive material such as tungsten, cobalt, ruthenium, iridium, molybdenum, copper, aluminum, or combinations thereof. In some embodiments, the metal layer 290 may be deposited using methods such as CVD, PVD, plating, and/or other suitable processes. In some embodiments, a seam 510, which may be an air gap, is formed in the metal layer 290 vertically between the channels 22A, 22B, 22C. In some embodiments, the metal layer 290 is conformally deposited on the work function metal layer 900. The seam 510 may form due to sidewall deposited film merging during the conformal deposition. In some embodiments, the seam 510 is not present between the neighboring channels 22A, 22B, 22C.

FIGS. 11A-22B depicts embodiments in which the source/drain layers 82L are replaced with high Ge % source/drains 82P to increase compressive strain on the channels 22. FIGS. 11A-22B depict a partial region 950 of the device 10 of FIG. 10A in which some elements are omitted from view for simplicity of illustration. For example, a single source/drain layer 82L is depicted in FIGS. 11A-22B that is replaced with the source/drain 82P, however additional source/drain layers 82L, such as those depicted in FIG. 10A, may be also replaced with source/drains similar to the source/drain 82P during and via the same process.

In FIGS. 11A and 11B, following formation of the gate structures 200, in preparation for forming source/drain contacts 120 in a later operation, source/drain contact openings 120O are formed in the ILD 130 that remove material of the ILD 130 to expose the source/drain layer 82L. In some embodiments, removal of the ILD 130 results in some removal of the source/drain layer 82L, such that an upper surface of the source/drain layer 82L is concave, as depicted in FIG. 11A. The removal of the ILD 130 may be via a suitable removal operation, such as a wet or dry etch, which may include a plasma etch, atomic layer etch (ALE), or the like.

Prior to removal of the ILD 130, a second etch stop layer (ESL) 136 may be formed on the upper surfaces of the gate structures 200, the gate spacers 41 and the ILD 130. Then, a second ILD 135 may be formed on the etch stop layer 136. Formation of the etch stop layer 136 and the second ILD 135 may be similar in most respects to that described for formation of the etch stop layer 131 and the ILD 130 with reference to FIGS. 10A and 10B.

When removing the ILD 130, an initial opening may be formed through the second ILD 135 and the etch stop layer 136, then second ILD 135 and the etch stop layer 136 including the initial opening may be used as a mask to remove the ILD 130 overlying the source/drain layers 82L. Removing the ILD 130 may then include etching the ILD 130 through the opening, for example, by an anisotropic, dry etch. The etching that removes the ILD 130 may remove exposed portions of the ILD 130 to a level that is below a top surface of the source/drain layers 82L, as depicted in FIG. 11B. Then, exposed portions of the ESL 131 may be removed from over the upper surface of the source/drain layer 82L, resulting in the upper surface being exposed, as depicted in FIG. 11B.

Following removal of the ILD 130, a protection or barrier side layer 132 may be formed in the opening 120O that covers the second ILD 135, the second ESL 136, the ILD 130, the ESL 131 and the source/drain layer 82L. The protection layer 132 may be a dielectric layer that is or includes one or more dielectric materials, such as SiO, SiN, SiC, SiON, SiOC, SiCN, SiOCN, or the like and may be deposited by a suitable deposition operation, such as a PVD, CVD, ALD or the like. The protection layer 132 may then be etched back via a dry etch to remove material of the protection layer 132 from upper surfaces of the second ILD 135, the source/drain layer 82L and the ILD 130, resulting in the protection layer 132 depicted in FIG. 11B.

Following formation of the protection layer 132, the source/drain layer 82L may be recessed slightly, resulting in the concave upper surface thereof depicted in FIG. 11A. Then, an additional sidewall isolation layer 133 may be formed on the protection layer 132 and the upper surface of the source/drain layer 82L. The sidewall isolation layer 133 may be a dielectric layer that is or includes one or more dielectric materials, such as SiO, SiN, SiC, SiON, SiOC, SiCN, SiOCN, or the like and may be deposited by a suitable deposition operation, such as a PVD, CVD, ALD or the like. The sidewall isolation layer 133 may then be etched back via a dry etch to remove material of the sidewall isolation layer 133 from the upper surface of the source/drain layer 82L and the ILD 130, resulting in the sidewall isolation layer 132 depicted in FIG. 11A.

As depicted in FIG. 11B, following formation of the source/drain opening 120O including recessing of the source/drain layer 82L after formation of the protection layer 132, the source/drain layer 82L may have an angled upper surface that slopes downward away from the protection layer 132.

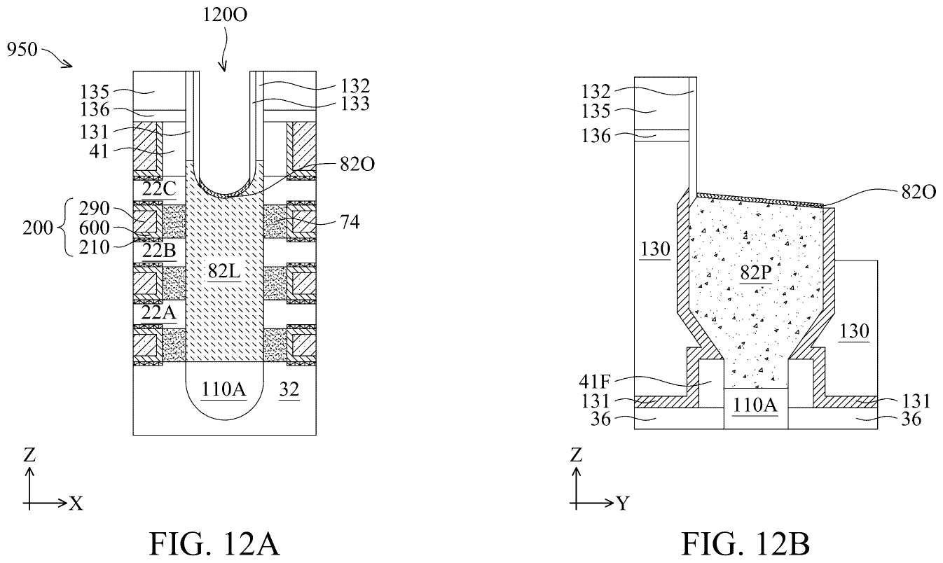

In FIGS. 12A and 12B, an oxidation process is performed that forms a porous oxide layer 82O over the sacrificial source/drain layer 82L on exposed upper surfaces thereof, corresponding to act 1500 of FIG. 24. Thickness of the porous oxide layer 82O may be in a range of about 0.8 nm to about 2 nm, such as about 1 nm. Formation of the porous oxide layer 82O may include thermal oxidation, where the SiGe sacrificial source/drain layer 82L is exposed to oxygen or water vapor at high temperatures. The thermal oxidation process can cause the silicon in the SiGe alloy to react with oxygen, forming silicon dioxide (SiO₂). Because germanium oxidizes differently than silicon, a less stable germanium oxide (GeOx) that can volatilize at the oxidation temperatures may be formed, affecting uniformity and quality of the porous oxide layer 82O. Namely, pores may be present in the porous oxide layer 82O that extend entirely through the porous oxide layer 82O such that the sacrificial source/drain layer 82L is exposed at least partially through the porous oxide layer 82O. The porous oxide layer 82O can have porosity that is sufficiently large to allow etchant and semiconductor precursor gases to pass therethrough while being sufficiently small for the porous oxide layer 82O to have enough mechanical strength that it will not break following or during removal of the source/drain layer 82L. The size of the pores of the porous oxide layer 82O may be in the range of approximately 1 Angstrom to 10 Angstroms.

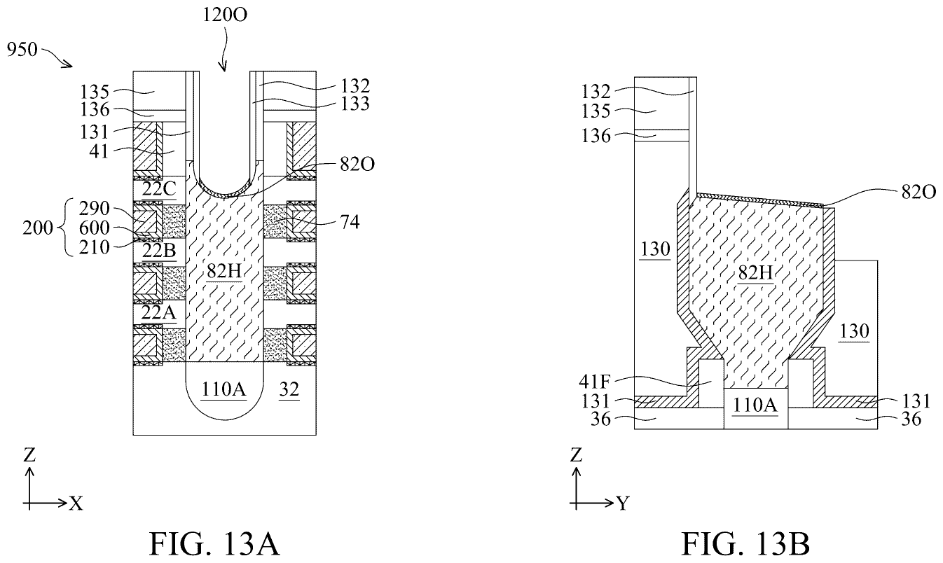

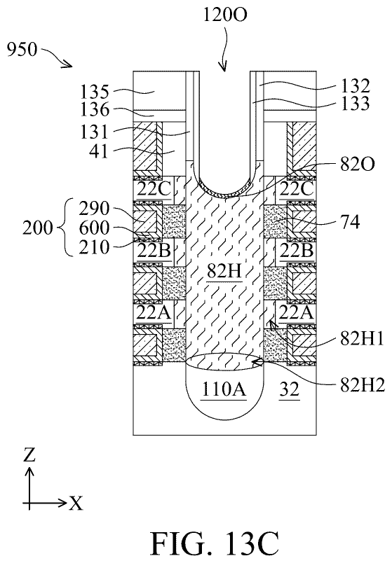

In FIGS. 13A-13C, the sacrificial source/drain layer 82L is removed to form openings 82H, corresponding to act 1600 of FIG. 24. The sacrificial source/drain layer 82L may be removed via a suitable etching operation, which may include a chlorine-based etchant, a fluorine-based etchant, or the like. The etchant, which can be a gas, may penetrate through pores of the porous oxide layer 82O and etch the SiGe of the sacrificial source/drain layer 82L, resulting in the sacrificial source/drain layer 82L being removed and the openings 82H being formed. The openings 82H may inherit shape of the sacrificial source/drain layer 82L, as depicted in FIGS. 13A and 13B.

In some embodiments, as depicted in FIG. 13C, some overetching may occur that removes end portions of the nanostructures 22, resulting in recesses 82H1. In some embodiments, instead of being due to overetching, the recesses 82H1 are formed due to removal of the semiconductor layers 82B that are described with reference to FIGS. 1A and 1B, which may be SiB layers. Namely, a first etch operation may remove the semiconductor material of the source/drain layer 82L, then a second etch operation may remove the semiconductor material of the semiconductor layers 82B. Also depicted in FIG. 13C, overetching during removal of the source/drain layer 82L may result in removal of material in the undoped semiconductor layer 110A, resulting in a recess 82H2.

Although not separately depicted in FIGS. 13A-13C, the device 10 may include NFETs in another region of the substrate 110 that have source/drains including a different material than that of the source/drain layers 82L. For example, the source/drain layers 82L may be Ge-containing layers of SiGe, GeSn, SiGeSn and the source/drains in the NFET device region of the substrate 110 may be silicon or another semiconductor material that does not include germanium. As such, the porous oxide layer 82O may be formed over the source/drain layers 82L in the PFET device region of the substrate 110 and a non-porous oxide layer may be formed over the source/drains in the NFET device region. Thus, the etchant gas(es) do not penetrate into the source/drains in the NFET device region. In some embodiments, the NFET device region includes source/drains that include a Ge-containing semiconductor material (e.g., SiGe, GeSn, SiGeSn), however the NFET device region may be masked during the operations described with reference to FIGS. 12A-13C such that the etchant gas(es) do not penetrate into the source/drains in the NFET device region.

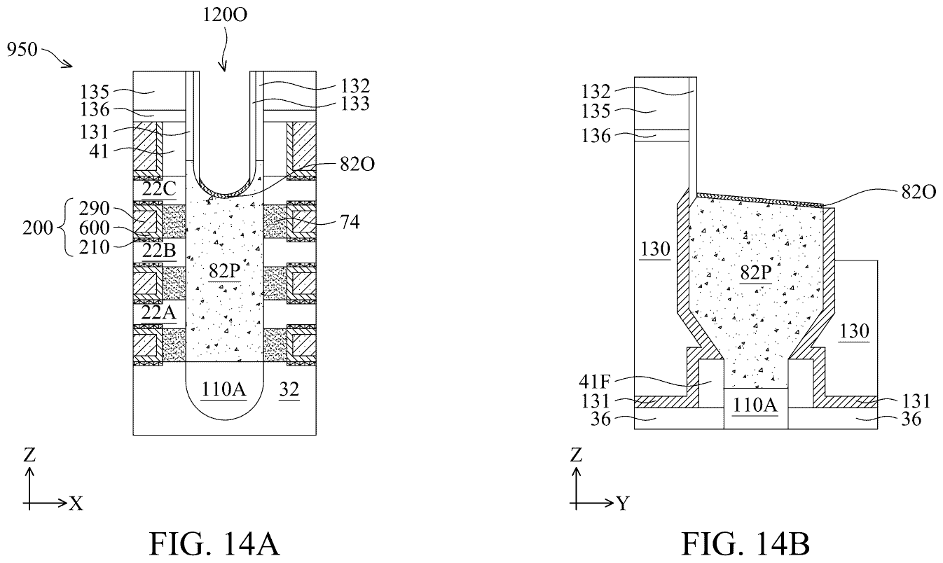

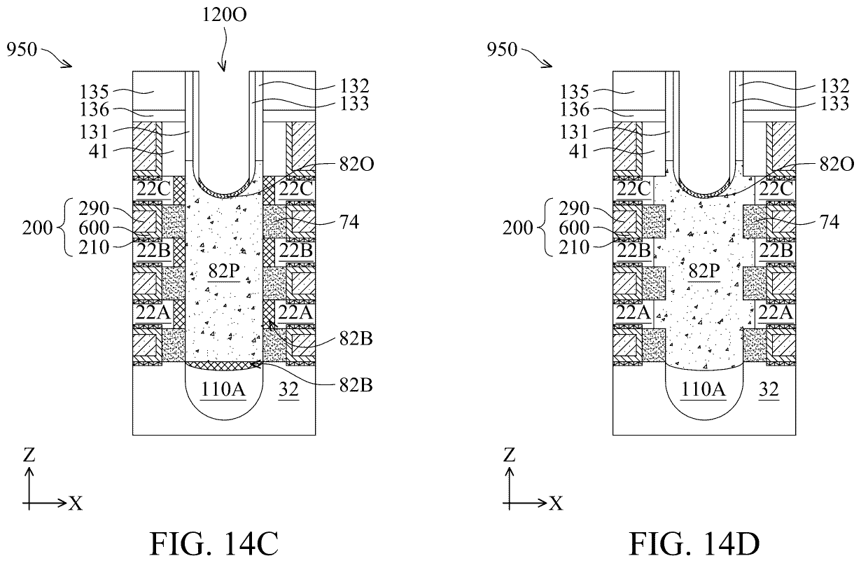

In FIGS. 14A-14D, following formation of the openings 82H, replacement or “active” source/drain regions 82P are formed in the openings 82H through the porous oxide layer 82O, corresponding to act 1700 of FIG. 4. The replacement source/drain regions 82P can be formed by a suitable epitaxial growth operation that grows material of the replacement source/drain regions 82P in the openings 82H. The replacement source/drain regions 82P can be or include one or more semiconductor materials, which can include SiGe, Ge, GeSn, SiGeSn. In the replacement source/drain regions 82P, concentration of germanium can be in a range of about 75% to 100% (i.e., pure Ge). Epitaxial growth of Ge or SiGe in the source/drain openings can be performed via chemical vapor deposition (CVD), molecular beam epitaxy (MBE), or the like. In CVD, gases containing the selected elements (e.g., germane for Ge, silane for Si, and optionally diborane, phosphine, TMGa, TEGa, AsH₃ or TBA for doping) are introduced into a reaction chamber. The device 10 can be heated to a high temperature, such that the gases react or decompose to form the epitaxial layer. CVD can be beneficial for good uniformity and control over layer composition. MBE can provide benefits of increased precision where the elements are evaporated in a high-vacuum environment and then condense on the heated device 10. MBE can provide excellent control over the thickness and composition of the epitaxial layer of the replacement source/drain regions 82P at the atomic level, beneficial for nanoscale devices.

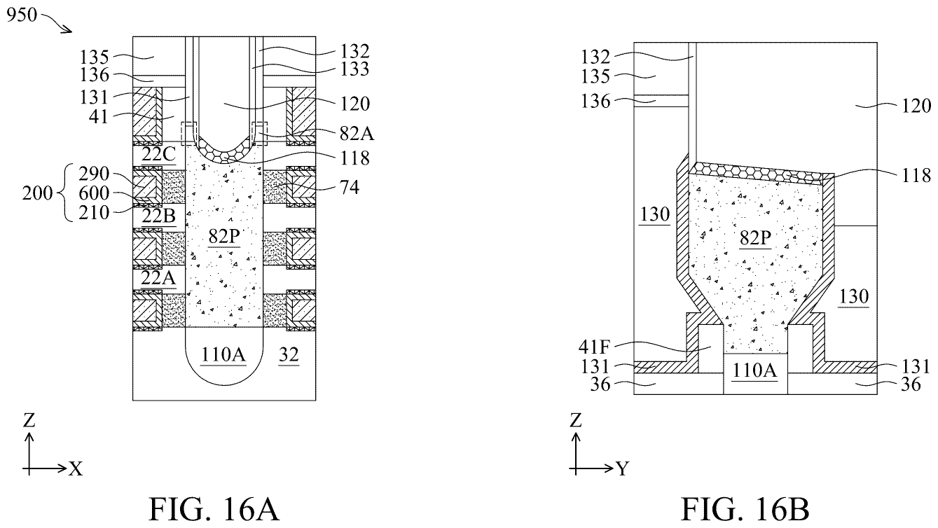

In CVD and MBE, the porous oxide layer 82O is permeable to the gases (e.g., germane, silane, diborane, phosphine, and the like), such that the gases may react or decompose at the nanostructures 22 in the openings 82H. Namely, exposed side surfaces of end portions of the nanostructures 22 can have the semiconductor material grown thereon. During the growth process, the growth may initially occur to form first regions on the end portions of the nanostructures 22. Then, as the process continues over time, the growth may continue such that the first regions enlarge and eventually merge to form second regions. Finally, growth continues until the second regions on either side of the opening 82H merge with each other and are in contact at least with the nanostructures 22, the inner spacers 74 and the porous oxide layer 82O. In some embodiments, one or more air gaps may be formed at corner regions of the replacement source/drain region 82P due to growth profile of the semiconductor material in the openings 82H. Formation of air gaps is described in greater detail with reference to FIGS. 16A and 16B.

In some embodiments, the dopants are introduced into the replacement source/drain regions 82P in situ, as described above. In some embodiments, the dopants include B, Ga, P, As or the like. In the growth process, diborane, phosphine, trimethylgallium, triethylgallium, arsine, tertiarybutylarsine or the like may be flowed in gaseous state to dope the replacement source/drain regions 82P in situ. In some embodiments, the replacement source/drain regions 82P may be doped in a subsequent operation, for example, by implantation of one or more of B, Ga, P, As or the like.

In FIG. 14C, the semiconductor layers 82B are in place in recesses between the inner spacers 74 abutting the channels 22 and on the undoped semiconductor layer 110A. As such, the replacement source/drains 82P may grow initially on exposed surfaces of the semiconductor layers 82B prior to merging.

In FIG. 14D, following the embodiment described with reference to FIG. 13C, the recesses 82H1, 82H2 are in place between the inner spacers 74 abutting the channels 22 and on the undoped semiconductor layer 110A. As such, the replacement source/drains 82P may grow initially on exposed surfaces of the channels 22 that are recessed back from outer surfaces of the inner spacers 74 and on the upper surface of the undoped semiconductor layer 110A prior to merging.

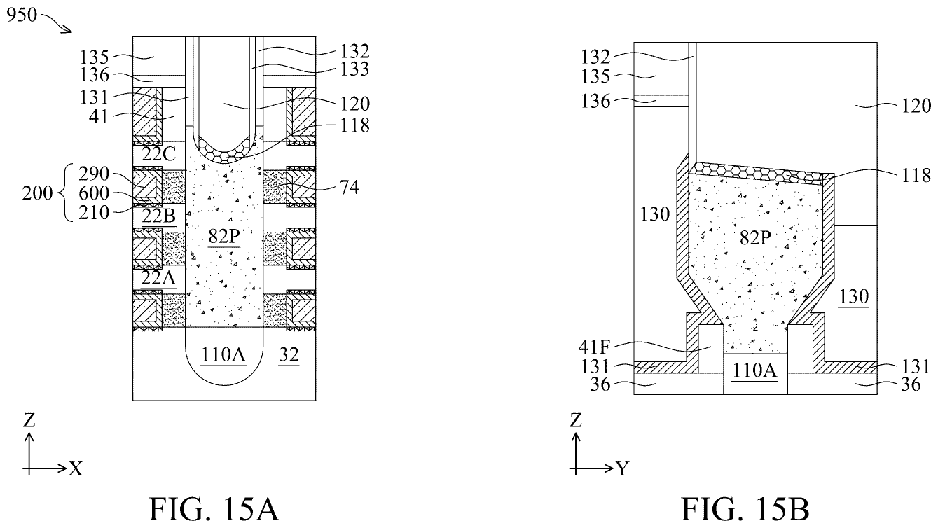

In FIGS. 15A and 15B, following formation of the replacement source/drain regions 82P, source/drain contacts 120 can be formed on the replacement source/drain regions 82P, corresponding to act 1800 of FIG. 24. Each source/drain contact 120 is positioned on and is electrically connected to a respective replacement source/drain region 82P. Electrical signals may be applied to the replacement source/drain regions 82P via the source/drain contacts 120.

The source/drain contacts 120 may be or include one or more conductive layers positioned on the replacement source/drain 82P. For example, a barrier or liner layer can include titanium nitride, tantalum nitride, titanium, tantalum, or other suitable conductive materials. A conductive fill layer can be on the barrier or liner layer and can include a conductive material such as tungsten, cobalt, ruthenium, titanium, aluminum, tantalum, or other suitable conductive materials. Other materials and configurations can be utilized for the source/drain contacts 120 without departing from the scope of the present disclosure.

The source/drain contacts 120 may include silicide 118. The silicide 118 is formed at the interface of the replacement source/drain regions 82P with the source/drain contacts 120. The silicide 118 may reduce the source/drain contact resistance. In some embodiments, the silicide 118 is or includes TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide 118 is or includes NiSi, CoSi, MnSi, Wsi, FeSi, RhSi, PdSi, RuSi, PtSi, IrSi, OsSi, or the like. The silicide 118 can be an alloy between the source/drain contact 120 and the replacement source/drain region 82P that can be a mixture of one or more of Ti, Ru, Mo, Ni, Co, W or the like and one or more of Ge, SiGe, SiGeSn, GeSn or the like. The silicide 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide 118 is present below, and in contact with, the cover layer 133.

FIGS. 16A and 16B depict optional air gaps 82A that may be present at corner regions of the replacement source/drain region 82P. The air gaps 82A may be present adjacent the silicide 118, the gate spacer 41, the protective layer 132 and the cover layer 133. Namely, the air gaps 82A may be laterally between the cover layer 133 and the gate spacer 41 and vertically between the source/drain 82P and the protective layer 132. As described previously with reference to FIGS. 14A-14D, during the growth process of the replacement source/drain region 82P, the growth may initially occur on the end portions of the nanostructures 22 to form first regions. Then, as the process continues over time, the growth may continue such that the first regions enlarge and eventually merge to form second regions. Finally, growth continues until the second regions on either side of the opening 82H merge with each other and are in contact at least with the nanostructures 22, the inner spacers 74 and the porous oxide layer 82O.

In some embodiments, growth of the second source/drain region 82P may terminate prior to the semiconductor material thereof reaching the bottom surface of the protection layer 132 immediately adjacent to the gate spacer 41, resulting in formation of the air gaps 82A. Height of the air gaps 82A in the Z-axis direction may be in a range of 0 nm to about 5 nm.

In the embodiments described with reference to FIGS. 2A-16B, instead of directly forming Ge in the source/drain opening 59, the SiGe source/drain layer 82L is formed, then the SiGe source/drain layer 82L is replaced with high Ge % SiGe or pure Ge, which can achieve various benefits. For example, germanium is prevented from diffusing into channels 22 in processes that would follow formation of the high Ge-concentration source/drains. The ILD 130 is also formed prior to forming the high Ge % source/drains, which can result in higher compressive strain to the channels 22 in the PFETs. Namely, the ILD 130 is formed after the initial source/drain formation process that forms the sacrificial source/drain layers 82L and NFET source/drains, whereas the ILD 130 is in place prior to replacing the sacrificial source/drain layer 82L with the high Ge % source/drain 82P.

In the embodiments described with reference to FIGS. 11A-16B, the sacrificial source/drain layer 82L is replaced following formation of the gate structures 200. In some embodiments, the sacrificial source/drain layers 82L may be replaced with the active source/drains 82P having high Ge % semiconductor material prior to formation of the gate structures 200.

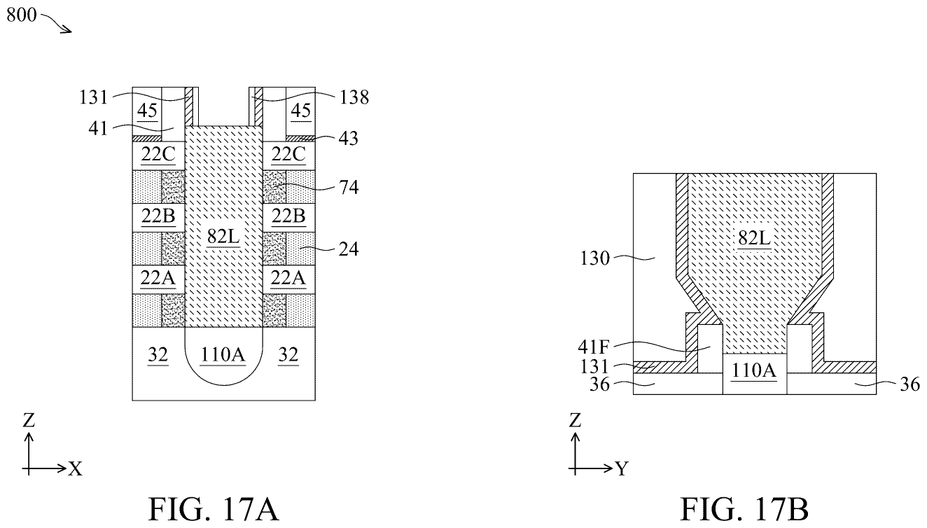

FIGS. 17A-22B depict views of a process in which the active source/drains 82P are formed by replacing the sacrificial source/drain layers 82L prior to formation of the gate structures 200 in accordance with various embodiments.

In FIGS. 17A and 17B, following formation of the ILD 130 and the ESL 131 and prior to formation of the replacement gate structures 200, the ILD 130 and the ESL 131 are recessed, resulting in the upper surface of the source/drain layer 82L being exposed. Recessing of the ILD 130 may be simultaneous (i.e., without leaving the chamber) or sequential with recessing of the ESL 131. For example, the ILD 130 and the ESL 131 may be removed from over the source/drain layer 82L by a removal process that removes material of the ILD 130 and the ESL 131 at substantially the same rate, such that a uniform depth is achieved across the trench in which the source/drain layer 82L is positioned. In this example, a physical bombardment technique, such as ion beam etching (IBE) may be performed to remove the material of the ILD 130 and the ESL 131 simultaneously. In another example, the ILD 130 may be removed to a first depth that exposes the ESL 131, then the ESL 131 may be removed to expose the source/drain layer 82L. In this example, first and second etches can be performed that remove the ILD 130 (e.g., silicon dioxide) then remove the ESL 131 (e.g., silicon nitride). In some embodiments, the source/drain layer 82L is recessed by the simultaneous process or the sequential process just described. In the sequential process, the source/drain layer 82L may be recessed by a third etch following removal of the ESL 131. The first, second and third etches may be wet or dry etches. In some embodiments, a cover layer 138 similar in most respects to the cover layer 133 described with reference to FIGS. 11A and 11B is formed following removal of the ILD 130 and the ESL 131, as depicted in FIG. 17A.

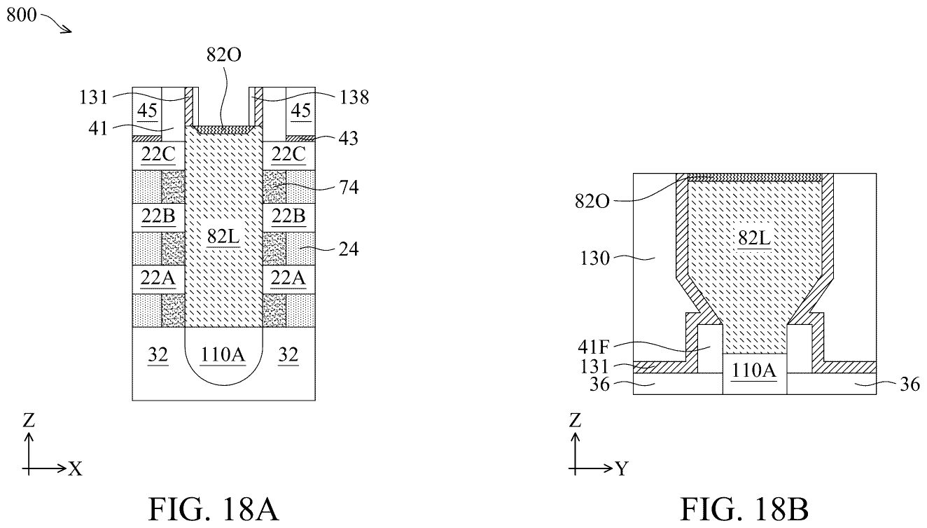

In FIGS. 18A and 18B, following exposing the upper surface of the source/drain layer 82L by removal of the ILD 130 and the ESL 131, a porous oxide layer 82O is formed on the exposed upper surface of the source/drain layer 82L. The porous oxide layer 82O may be similar in most respects to the porous oxide layer 82O described with reference to FIGS. 12A and 12B and may be formed in a manner similar to that described with reference to FIGS. 12A and 12B. The porous oxide layer 82O is on the upper surface of the source/drain layer 82L and includes SiO and GeO or SiGeO that has pores that extend therethrough to expose the source/drain layer 82L. The porous oxide layer 82O can have porosity that is sufficiently large to allow etchant and semiconductor precursor gases to pass therethrough while being sufficiently small for the porous oxide layer 82O to have enough mechanical strength that it will not break during or following removal of the source/drain layer 82L. In some embodiments, as depicted in FIG. 18A, the porous oxide layer 82O can extend beneath the cover layer 138.

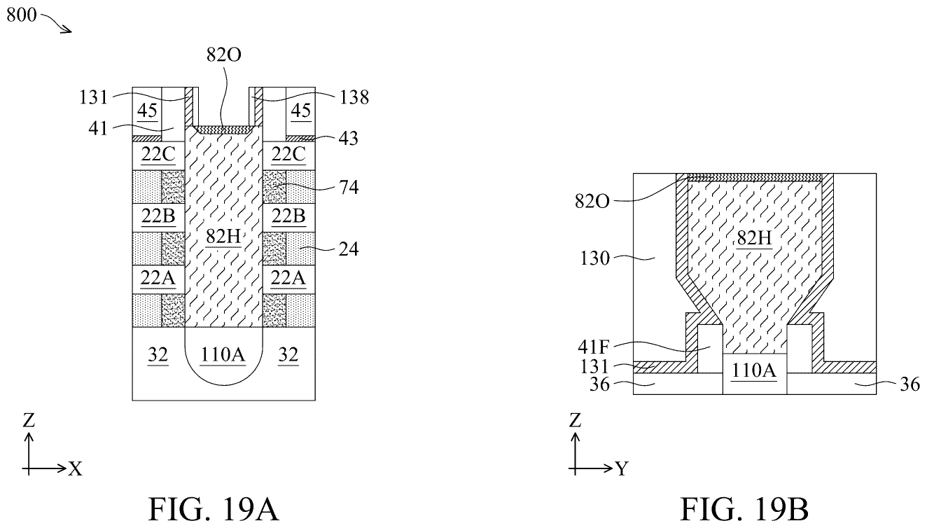

In FIGS. 19A and 19B, following formation of the porous oxide layer 82O, the source/drain layer 82L is removed. Removal of the source/drain layer 82L in FIGS. 19A and 19B can be similar in most respects to that described with reference to FIGS. 13A-13C. The removal can form the opening 82H, which can optionally include recesses in the channels 22 and/or the undoped semiconductor layer 110 as described with reference to FIG. 15C.

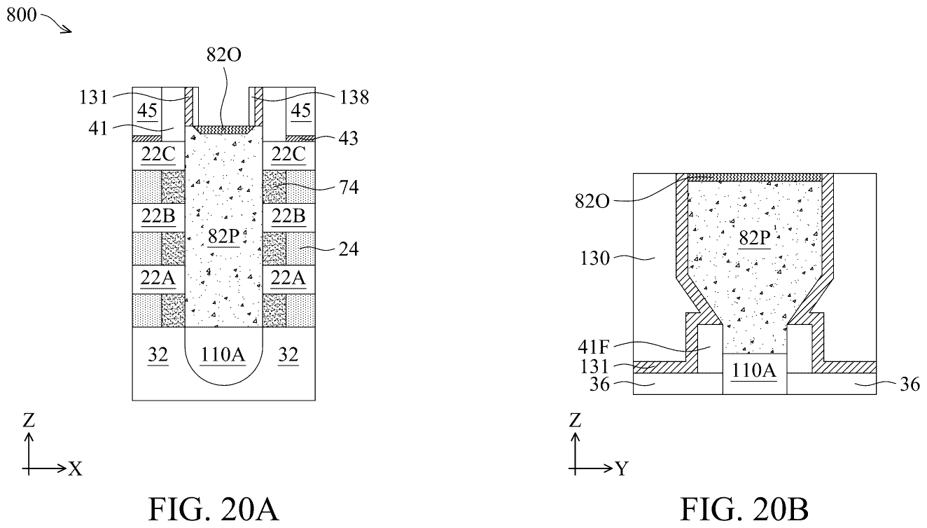

In FIGS. 20A and 20B, following formation of the opening 82H by removing the source/drain layer 82L, the replacement source/drain 82P can be formed in the opening 82H. Formation of the replacement source/drain 82P is similar in most respects to that described with reference to FIGS. 14A and 14B. In some embodiments, the formation of the replacement source/drain 82P in FIGS. 20A and 20B results in the air gaps 82A described with reference to FIGS. 16A and 16B. Following replacement of the source/drain layer 82L with the replacement source/drain 82P, the porous oxide layer 82O can be removed by a suitable removal process, such as a clean or a wet etch that is selective to material of the porous oxide layer 82O without substantially removing material of the source/drain 82P.

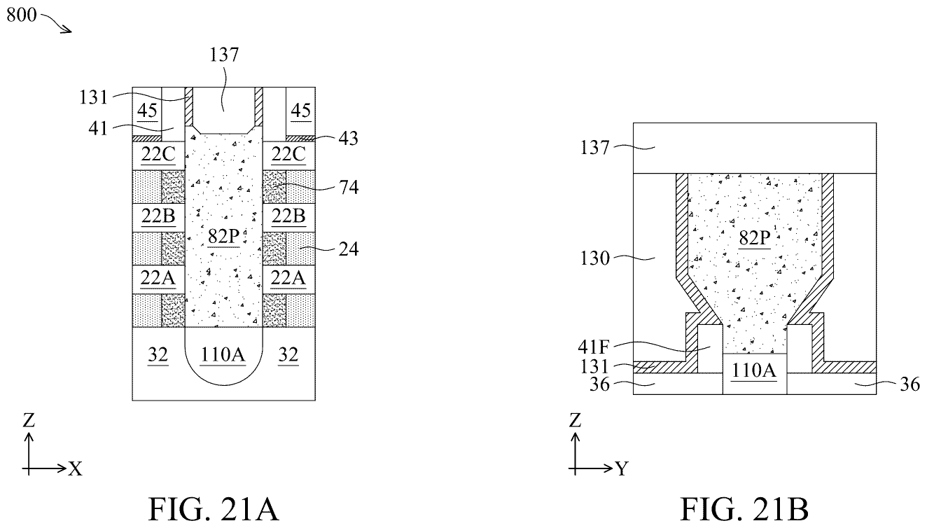

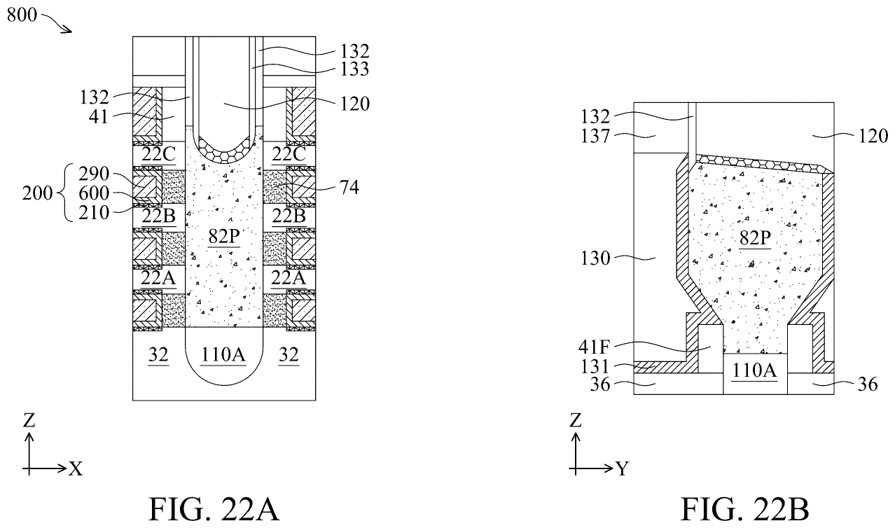

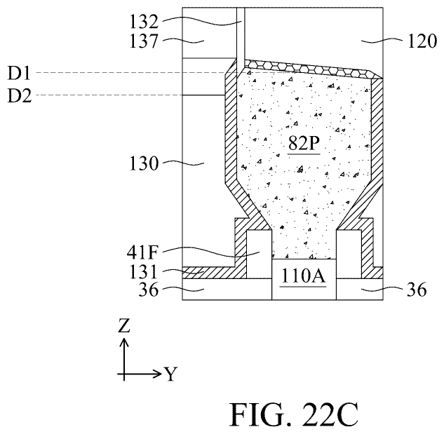

In FIGS. 21A-22C, following formation of the replacement source/drain 82P, the replacement gate structure 200 and source/drain contacts 120 can be formed. Because the ILD 130 and ESL 131 were removed to expose the source/drain layer 82L as described with reference to FIGS. 17A and 17B, the source/drain 82P is initially exposed. Prior to forming the replacement gate structure 200, the nanostructures 24 are removed via etching, which can damage the source/drain 82P if not protected.

In FIGS. 21A and 21B, a top dielectric layer 137 is formed in the trench over the source/drain 82P covering the source/drain 82P, the ILD 130 and the ESL 131. In some embodiments, prior to forming the top dielectric layer 137, the cover layer 138 is removed by a suitable etch operation. The top dielectric layer 137 may be or include one or more dielectric materials, such as SiN, SiON, SiCN, SiOCN or the like. Thickness or height in the Z-axis direction of the top dielectric layer 137 may be in a range of about 1 nm to about 25 nm. Namely, the top dielectric layer 137 may extend from an upper surface of the source/drain 82P to be coplanar with an upper surface of the gate spacer 41. The top dielectric layer 137 may be formed by a suitable deposition operation, such as a PVD, CVD, ALD, or the like, which may be followed by a CMP to remove excess material of the top dielectric layer 137 from over the gate spacers 41 and the sacrificial gate layer 45. Due to the CMP, the upper surfaces of the dielectric layer 137 and the gate spacers 41 may be coplanar.

In FIGS. 22A-22C, following formation of the top dielectric layer 137, the gate structures 200 and source/drain contacts 120 may be formed. The gate structures 200 may be formed in a manner similar to that described with reference to FIGS. 10A, 10B and 23. The source/drain contacts 120 may be formed in a manner similar to that described with reference to FIGS. 15A and 15B.

As depicted in FIG. 22B, due to formation of the top dielectric layer 137, in the profile in the Y-Z plane, the top dielectric layer 137 may be adjacent the source/drain contact 120 and separated therefrom by the protection layer 132.

As depicted in FIG. 22C, in some embodiments, the top dielectric layer 137 can extend to a depth or level D2 that is below a depth or level D1 of a bottom surface of the source/drain contact 120. This can be due to etching the ILD 130 to a level that is below an upper surface of the source/drain layer 82L in the operation described with reference to FIGS. 17A and 17B.

Embodiments may provide advantages. Replacing the SiGe source/drains with high Ge % source/drains instead of forming the high Ge % source/drains directly in the source/drain openings prevents Ge from diffusing into the channels and allows the ILD to be in place to better constrain growth of the Ge, which leads to higher strain in the channels. The high Ge % or pure Ge source/drains increase lattice constant, thereby increasing channel strain and associated drive current. Source/drain contact resistance can also be reduced, which is beneficial to improve current output.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In accordance with at least one embodiment, a method is provided that includes forming a stack of nanostructure channels over a substrate by forming a source/drain opening. The method also includes forming a sacrificial source/drain in the source/drain opening. The method also includes increasing tensile strain of the stack of nanostructure channels by replacing the sacrificial source/drain with a replacement source/drain having germanium concentration that exceeds that of the sacrificial source/drain.

In accordance with at least one embodiment, a method is provided that includes forming a stack of nanostructures over a substrate by forming a source/drain opening through a multi-layer lattice including alternating first semiconductor layers and second semiconductor layers. The method also includes forming a sacrificial gate structure on the stack of nanostructures. The method also includes forming a gate spacer adjacent the sacrificial gate structure. The method also includes forming a sacrificial source/drain in the source/drain opening. The method also includes forming an etch stop layer on the sacrificial source/drain. The method also includes forming an interlayer dielectric on the etch stop layer. The method also includes exposing an upper surface of the sacrificial source/drain by removing an upper portion of the interlayer dielectric and an upper portion of the etch stop layer. The method also includes replacing the sacrificial source/drain with a replacement source/drain. The method also includes after the replacing the sacrificial source/drain, forming an active gate by replacing the sacrificial gate structure and interposers of the stack of nanostructures.

In accordance with at least one embodiment, a device is provided that includes a first nanostructure channel. The device also includes a second nanostructure channel over the first nanostructure channel. The device also includes an inner spacer between the first nanostructure channel and the second nanostructure channel. The device also includes a gate spacer on the second nanostructure channel. The device also includes a source/drain abutting the first and second nanostructure channels, the source/drain including an upper recess that extends to a first depth, the source/drain having germanium concentration that exceeds about 75%. The device also includes a source/drain contact on the source/drain, the source/drain contact extending into the upper recess. The device also includes a cover layer between the source/drain contact and the gate spacer, the cover layer extending into the upper recess to a second depth that is above the first depth. The device also includes a protection layer between the gate spacer and the cover layer, the protection layer extending to a level above a bottom surface of the gate spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of nanostructure channels over a substrate by forming a source/drain opening;
forming a sacrificial source/drain in the source/drain opening; and
increasing tensile strain of the stack of nanostructure channels by replacing the sacrificial source/drain with a replacement source/drain having germanium concentration that exceeds that of the sacrificial source/drain.

2. The method of claim 1, wherein the replacing the sacrificial source/drain includes replacing a silicon germanium source/drain with a substantially pure germanium source/drain having germanium concentration that exceeds about 99%.

3. The method of claim 1, wherein the replacing the sacrificial source/drain includes replacing a silicon germanium source/drain with a high-concentration germanium source/drain having germanium concentration that exceeds about 80%.

4. The method of claim 1, wherein the replacing the sacrificial source/drain includes replacing a silicon germanium source/drain having germanium concentration that does not exceed about 40% with a silicon germanium source/drain having germanium concentration that exceeds about 50%.

5. The method of claim 1, wherein the replacing the sacrificial source/drain includes:
forming a porous oxide layer on an upper surface of the sacrificial source/drain;
removing the sacrificial source/drain through pores of the porous oxide layer; and
growing the replacement source/drain through the pores of the porous oxide layer.

6. The method of claim 5, further comprising:
removing the porous oxide layer; and
forming a source/drain contact on the replacement source/drain.

7. The method of claim 6, further comprising, prior to the replacing the sacrificial source/drain:
forming an opening by removing interposers of the stack of nanostructure channels; and
forming an active gate in the opening.

8. A method, comprising:
forming a stack of nanostructures over a substrate by forming a source/drain opening through a multi-layer lattice including alternating first semiconductor layers and second semiconductor layers;
forming a sacrificial gate structure on the stack of nanostructures;
forming a gate spacer adjacent the sacrificial gate structure;
forming a sacrificial source/drain in the source/drain opening;
forming an etch stop layer on the sacrificial source/drain;
forming an interlayer dielectric on the etch stop layer;
exposing an upper surface of the sacrificial source/drain by removing an upper portion of the interlayer dielectric and an upper portion of the etch stop layer;
replacing the sacrificial source/drain with a replacement source/drain; and
after the replacing the sacrificial source/drain, forming an active gate by replacing the sacrificial gate structure and interposers of the stack of nanostructures.

9. The method of claim 8, wherein the replacing the sacrificial source/drain includes:
forming a porous oxide layer on the exposed upper surface of the sacrificial source/drain;
forming an opening by removing the sacrificial source/drain through pores of the porous oxide layer; and
growing the replacement source/drain through the pores of the porous oxide layer.

10. The method of claim 9, wherein the growing the replacement source/drain includes growing a semiconductor material having germanium concentration in a range of about 75% to 100%.

11. The method of claim 9, wherein the growing the replacement source/drain includes growing a semiconductor material including SiGe, Ge, GeSn or SiGeSn.

12. The method of claim 11, wherein the growing a semiconductor material includes growing the semiconductor material having dopant concentration in a range of about 1e19/cm³ to about 5e21/cm³.

13. The method of claim 9, wherein the growing the replacement source/drain does not completely fill the opening such that an air gap is positioned adjacent the gate spacer.

14. The method of claim 8, further comprising, prior to the forming an active gate, forming a dielectric layer covering an upper surface of the replacement source/drain, an upper surface of the interlayer dielectric and an upper surface of the etch stop layer.

15. A device, comprising:
a first nanostructure channel;
a second nanostructure channel over the first nanostructure channel;
an inner spacer between the first nanostructure channel and the second nanostructure channel;
a gate spacer on the second nanostructure channel;
a source/drain abutting the first and second nanostructure channels, the source/drain including an upper recess that extends to a first depth, the source/drain having germanium concentration that exceeds about 75%;
a source/drain contact on the source/drain, the source/drain contact extending into the upper recess;
a cover layer between the source/drain contact and the gate spacer, the cover layer extending into the upper recess to a second depth that is above the first depth; and
a protection layer between the gate spacer and the cover layer, the protection layer extending to a level above a bottom surface of the gate spacer.

16. The device of claim 15, further comprising an air gap positioned laterally between the cover layer and the gate spacer and vertically between the protection layer and the source/drain.

17. The device of claim 15, further comprising a silicide layer between the source/drain and the source/drain contact.

18. The device of claim 15, wherein the protection layer is immediately adjacent a side surface of the source/drain, the device further comprising:
an interlayer dielectric adjacent a side surface of the protection layer; and
a dielectric layer on an upper surface of the interlayer dielectric, the upper surface being at a second level that is below a bottom surface of the source/drain contact.

19. The device of claim 18, wherein the dielectric layer has thickness in a range of about 1 nanometer to about 25 nanometers.

20. The device of claim 15, further comprising a semiconductor layer between the source/drain and the first nanostructure channel, the semiconductor layer including SiB.
